(19) United States
(12) Patent Application Publication
(10) Pub. No.: US 2015/0034141 A1
(43) Pub. Date: Feb. 5, 2015

(54) Photovoltaic Cell And An Article Including An Isotropic Or Anisotropic Electrically Conductive Layer

(71) Applicant: Dow Corning Corporation, Midland, MI (US)

(72) Inventors: John D. Albaugh, Freeland, MI (US); Tiffany Menjoulet, Clare, MI (US); Timothy Paul Mitchell, Clio, MI (US); Nicholas E. Powell, Midland, MI (US)

(21) Appl. No.: 14/364,848

(22) PCT Filed: Dec. 13, 2012
(86) PCT No.: PCT/US2012/069552

§ 371 Date: Jun. 12, 2014

Related U.S. Application Data
(60) Provisional application No. 61/663,249, filed on Jun. 22, 2012.
(60) Provisional application No. 61/570,768, filed on Dec. 14, 2011.

(51) Int. Cl. H01L 31/02; H01B 1/22; H01L 31/18

(52) U.S. Cl. CPC H01L 31/02008; H01L 31/18; H01B 1/22
USPC 136/244; 438/98; 136/256; 252/512; 174/126.2

(57) ABSTRACT

A photovoltaic (PV) cell comprises a base substrate which comprises silicon and includes at least one doped region. The PV cell further comprises a collector disposed on the doped region of the base substrate and having a lower portion in physical contact with the doped region of the base substrate, and an upper portion opposite the lower portion. The PV cell further comprises an electrically conductive layer which is electrically isotropic or anisotropic and disposed adjacent the collector. The electrically conductive layer is in electrical communication with the base substrate via the collector. The electrically conductive layer comprises a binder and electrically conductive particles comprising at least one metal selected from the group consisting of Group 8 through Group 14 metals of the Periodic Table of Elements. The electrically conductive particles impart isotropic or anisotropic electrical conductivity to the electrically conductive layer.

### CROSS REFERENCE TO RELATED APPLICATIONS

This application claims the benefit of U.S. Provisional Patent Application Ser. No. 61/570,768, filed on Dec. 14, 2011, and U.S. Provisional Patent Application Ser. No. 61/663,249, filed on Jun. 22, 2012, the disclosures of which are incorporated herewith by reference in their entirety.

### FIELD OF THE INVENTION

The present invention generally relates to a photovoltaic cell (PV) as well as to an article for an assembly of associated PV cells. The PV cell and article both include an isotropic or anisotropic electrically conductive layer.

### BACKGROUND

Front and rear surface metallization is an important aspect of photovoltaic (PV) cells which allows for collection and transport of charge carriers. In front PV cell constructs, the metallization is generally in the form of a grid, which includes narrow lines or “fingers” of conductive material which connect to thicker busbars. In rear PV cell constructs, the metallization is generally in the form of an electrode (e.g. a layer of aluminum), which typically includes contacts formed from Ag. The contacts are disposed through the rear layer. The contacts can be in the form of busbars or pads. Tabbing, e.g. ribbon, is soldered to the contacts/busbars/pads to connect multiple PV cells together (e.g. in series) and ultimately transport current.

Traditional solder includes lead (Pb) as a primary component due to its excellent conductivity and ease of manipulation. Aside from the known risks associated with Pb, use of traditional solders in PV cells typically requires higher temperature processing resulting in thermal stress of the PV cell. Additionally, use of traditional solders in PV cells can result in high points on, or bowing of, the PV cells. As such, there remains an opportunity to provide improved materials which are suitable for current transport and/or electrical connection in PV cell applications.

### SUMMARY OF THE INVENTION

The present invention provides a photovoltaic (PV) cell comprising a base substrate which comprises silicon. The PV cell includes at least one doped region. The PV cell further comprises a collector disposed on the doped region of the base substrate. The collector has a lower portion in physical contact with the doped region of the base substrate, and an upper portion opposite the lower portion. The PV cell further comprises an electrically conductive layer that is electrically isotropic or anisotropic. The electrically conductive layer is disposed adjacent the collector and is in electrical communication with the base substrate via the collector. The electrically conductive layer comprises a binder and electrically conductive particles. The electrically conductive particles comprise at least one metal selected from the group consisting of Group 8 through Group 14 metals of the Periodic Table of Elements. The electrically conductive particles impart isotropic or anisotropic electrical conductivity to the electrically conductive layer. The PV cell can be useful for a variety of applications, such as for converting light of many different wavelengths into electricity.

The present invention also provides an article for an assembly of associated photovoltaic cells. The article comprises a ribbon for carrying electric current and an electrically conductive layer. The electrically conductive layer is as set forth above. The article can be useful for a variety of applications, such as being configured in a PV cell.

The present invention further provides an electrically conductive silicone composition that is electrically isotropic or anisotropic for forming an electrically conductive layer in a photovoltaic cell. The electrically conductive silicone composition comprises a silicone composition and electrically conductive particles. These electrically conductive particles are as set forth above. The electrically conductive particles impart isotropic or anisotropic electrical conductivity to the electrically conductive silicone composition. The electrically conductive silicone composition can be useful for a variety of applications, such as being configured in a PV cell to form an electrically conductive layer.

The present invention still further provides a method of forming a PV cell comprising a base substrate comprising silicon and including at least one doped region. The PV cell also comprises a collector disposed on the doped region of the base substrate and has a lower portion in physical contact with the doped region of the base substrate, and an upper portion opposite the lower portion. The method comprises the step of applying an electrically conductive composition which is electrically isotropic or anisotropic adjacent to the collector. The electrically conductive composition comprises a binder. The electrically conductive composition further comprises electrically conductive particles. The electrically conductive particles are as set forth above and impart isotropic or anisotropic electrical conductivity to the electrically conductive composition. The electrically conductive composition further comprises a solvent comprising a hydrocarbon having from 1 to 30 carbon atoms. The method further comprises the step of removing or substantially removing the solvent from the electrically conductive composition to form an electrically conductive layer. The method may be used for various applications, such as for forming a PV cell to convert light of many different wavelengths into electricity.

### BRIEF DESCRIPTION OF THE DRAWINGS

The present invention may be readily appreciated, as the same becomes better understood by reference to the following detailed description when considered in connection with the accompanying drawings wherein:

FIG. 1A is a front view of an embodiment of a PV cell including a base substrate, a passivation layer, a collector comprising a plurality of fingers, and a pair of busbars;

FIG. 1B is a rear view of an embodiment of a PV cell including a base substrate, a collector comprising a first electrode, and three sets of second electrodes configured as contact pads;

FIG. 2 is a partial cross-sectional side view of another embodiment of a PV cell illustrating an upper doped region of a base substrate, a collector comprising a plurality of fingers, and an electrically conductive layer;

FIG. 3 is a partial cross-sectional side view of another embodiment of a PV cell illustrating an upper doped region of a base substrate, a collector comprising a plurality of fingers, an electrically conductive layer, and a ribbon;

FIG. 4 is a partial cross-sectional side view of another embodiment of a PV cell illustrating an upper doped region of a base substrate, a collector comprising a plurality of fingers, a passivation layer, and an electrically conductive layer;

FIG. 5 is a partial cross-sectional side view of another embodiment of a PV cell illustrating an upper doped region of a base substrate, a collector comprising a plurality of fingers, a passivation layer, an electrically conductive layer, and a ribbon;

FIG. 6 is a partial cross-sectional side view of another embodiment of a PV cell illustrating an upper doped region of a base substrate, a collector comprising a plurality of fingers, a busbar, and an electrically conductive layer;

FIG. 7 is a partial cross-sectional side view of another embodiment of a PV cell illustrating an upper doped region of a base substrate, a collector comprising a plurality of fingers, a busbar, an electrically conductive layer, and a ribbon;

FIG. 8 is a partial cross-sectional side view of another embodiment of a PV cell illustrating an upper doped region of a base substrate, a collector comprising a plurality of fingers, a passivation layer, a busbar, and an electrically conductive layer;

FIG. 9 is a partial cross-sectional side view of another embodiment of a PV cell illustrating an upper doped region of a base substrate, a collector comprising a plurality of fingers, a passivation layer, a busbar, an electrically conductive layer, and a ribbon;

FIG. 10 is a diagram illustrating the polymers curing and solder reflow of an electrically conductive composition during formation of a conductor;

FIG. 11 is a magnified cross-sectional side view of the electrically conductive composition after forming the conductor illustrating polymers after cure, solder after reflow, metal particles, and an inter-metallic layer between the solder and metal particles;

FIG. 12 is a partial cross-sectional side view of another embodiment of a PV cell illustrating a rear doped region of a base substrate, a collector comprising a first electrode, a second electrode, and an electrically conductive layer;

FIG. 13 is a partial cross-sectional side view of another embodiment of a PV cell illustrating a rear doped region of a base substrate, a collector comprising a first electrode, a second electrode, an electrically conductive layer, and a ribbon;

FIG. 14 is a partial cross-sectional side view of another embodiment of a PV cell illustrating a rear doped region of a base substrate, a collector comprising a first electrode having the form of a contact grid comprising fingers, a passivation layer, a second electrode, and an electrically conductive layer;

FIG. 15 is a partial cross-sectional side view of another embodiment of a PV cell illustrating a rear doped region of a base substrate, a collector comprising a first electrode having the form of a contact grid comprising fingers, a passivation layer, a second electrode, an electrically conductive layer, and a ribbon;

FIG. 16 is a cross-sectional side view of an embodiment of a PV cell illustrating upper and rear doped regions of a base substrate, a passivation layer, a collector comprising the plurality of fingers, a busbar, an additional collector comprising a first electrode, a set of second electrodes, and a plurality of electrically conductive layers;

FIG. 17 is a cross-sectional side view of an embodiment of a PV cell illustrating upper and rear doped regions of a base substrate, a passivation layer, a collector comprising a plurality of fingers, a busbar, an additional collector comprising a first electrode, a set of second electrodes, a plurality of electrically conductive layers, and a plurality of ribbons;

FIG. 18 is a partial cross-sectional perspective view of an embodiment of a PV cell illustrating upper and rear doped regions of a base substrate, a passivation layer, a collector comprising a plurality of fingers, an additional collector comprising a first electrode, a plurality of electrically conductive layers, and a plurality of ribbons with one of the ribbons being disposed on one of the electrically conductive layers of the PV cell;

FIG. 19 is a partial cross-sectional perspective view of an embodiment of a PV cell illustrating upper and rear doped regions of a base substrate, a passivation layer, a collector comprising a plurality of fingers, a pair of busbars, an additional collector comprising a first electrode, a pair of second electrodes, and a plurality of electrically conductive layers with one of the electrically conductive layers being disposed on one of the busbars of the PV cell;

FIG. 20 is the PV cell of FIG. 19 and a plurality of ribbons with one of the ribbons being disposed on one of the electrically conductive layers of the PV cell;

FIG. 21 is a partial cross-sectional perspective view of an embodiment of an article for an assembly of associated photovoltaic cells illustrating a ribbon and an electrically conductive layer;

FIG. 22 is a schematic front view of an embodiment of a PV cell including a passivation layer, discontinuous-fingers, and a busbar;

FIG. 23 is a schematic front view of an embodiment of a PV cell including a passivation layer, discontinuous-fingers, supplemental fingers, and a busbar;

FIG. 24 is a schematic front view of an embodiment of a PV cell including a passivation layer, fingers, a busbar, and supplemental busbar pads;

FIG. 25 is a schematic front view of an embodiment of a PV cell including a passivation layer, fingers, a pair of busbars, and a supplemental busbar;

FIG. 26 is a schematic front view of an embodiment of a PV cell including a passivation layer, fingers having pads, and a busbar;

FIG. 27 is a schematic front view of an embodiment of a PV cell including a passivation layer, fingers having hollow pads, and a busbar; and

FIG. 28 is a schematic front view of an embodiment of a PV cell including a passivation layer, discontinuous-fingers, supplemental fingers, and a busbar.

### DETAILED DESCRIPTION OF THE INVENTION

Referring now to the Figures, wherein like numerals indicate like parts throughout the several views, a photovoltaic (PV) cell is generally shown at 30. PV cells 30 are useful for converting light of many different wavelengths into electricity. As such, the PV cell 30 can be used for a variety of applications. For example, a plurality of PV cells 30 in electrical communication can be used in a photovoltaic module (not shown). The photovoltaic module can be used in a variety of locations and for a variety of applications, such as in residential, commercial, or industrial, applications. For example, the photovoltaic module can be used to generate electricity, which can be used to power electrical devices (e.g. lights and electric motors), or the photovoltaic module can be used to shield objects from sunlight (e.g. shield automobiles parked under photovoltaic modules that are disposed over parking spaces). The PV cell 30 is not limited to any particular type of use. The figures are not drawn to scale. As such, certain components of the PV cell 30 may be larger or smaller than as depicted.

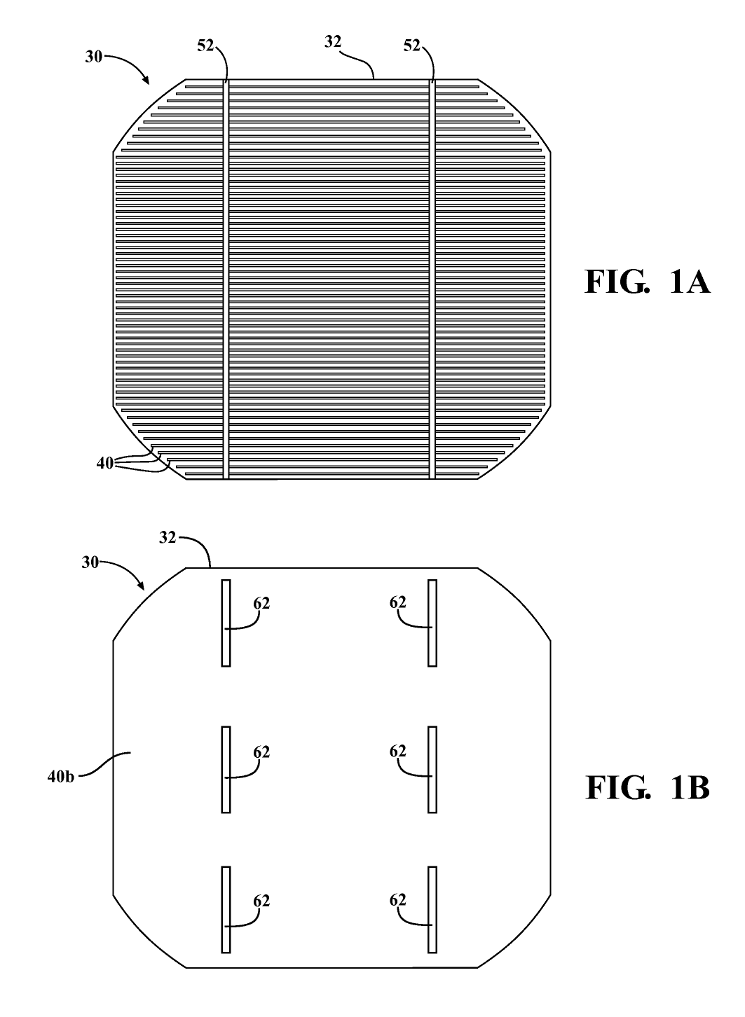

Referring to FIGS. 1A and 1B, the PV cell 30 is shown in a square configuration with rounded corners, i.e., a pseudo-square. While this configuration is shown, the PV cell 30 may be configured into various shapes. For example, the PV cell 30 may be a rectangle with corners, a rectangle with rounded or curved corners, a circle, etc. The PV cell 30 is not limited to any particular shape. The PV cell 30 can be of various sizes, such as 4 by 4 inch (10.2 by 10.2 cm) squares, 5 by 5 inch (12.7 by 12.7 cm) squares, 6 by 6 inch (15.2 by 15.2 cm) squares, etc. The PV cell 30 is not limited to any particular size. Specific suitable examples of PV cells are disclosed in U.S. Ser. Application No. 61/569,977 and 61/569,992, each of which are hereby incorporated by reference in their entirety to the extent they do not conflict with the general scope of this invention.

The present invention provides the PV cell 30 comprising a base substrate 32 which comprises silicon. The PV cell 30 includes at least one doped region selected from the group consisting of an upper doped region 34, a rear doped region 38, and combinations of the upper doped region 34 spaced from and opposite the rear doped region 38. The PV cell 30 further comprises a collector 40 disposed on the doped region 34, 38 of the base substrate 32. The collector 40 has a lower portion 42 in physical contact with the doped region 34, 38 of the base substrate 32, and an upper portion 44 opposite the lower portion 42. The PV cell 30 further comprises an electrically conductive layer 39 that is electrically isotropic or anisotropic and disposed adjacent the collector 40. The electrically conductive layer 39 is in electrical communication with the base substrate 32 via the collector 40. The electrically conductive layer 39 comprises a binder and electrically conductive particles. The electrically conductive particles comprise at least one metal selected from the group consisting of Group 8 through Group 14 metals of the Periodic Table of Elements.

It is to be appreciated that the term “adjacent” does not require physical contact, e.g. a first structure may be adjacent to a second structure even though the first and second structures are physically separated via one or more intermediate structures. However, in certain embodiments described below, the term “adjacent” does refer to physical contact, e.g. direct physical contact between a first structure and a second structure.

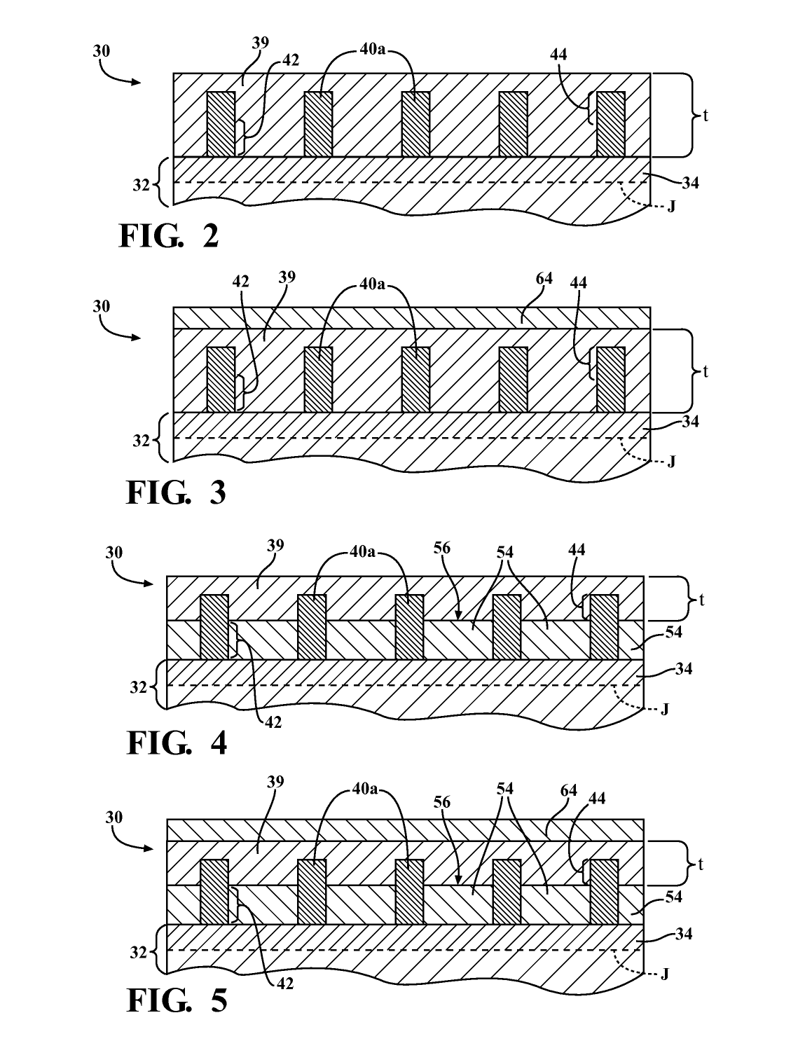

Referring to FIGS. 2 through 9, the PV cell 30 comprises the base substrate 32. The base substrate 32 comprises silicon. The silicon may also be referred to in the art as a semiconductor material. Various types of silicon can be utilized, such as monocrystalline silicon, polycrystalline silicon, amorphous silicon, or combinations thereof. In certain embodiments, the base substrate 32 comprises crystalline silicon, e.g. monocrystalline silicon. The PV cell 30 is generally referred to in the art as a wafer type PV cell 30. Wafers are thin sheets of silicon that are typically formed from mechanically sawing the wafer from a single (mono) crystal or multicrystal silicon ingot. Alternatively, wafers can be formed from casting silicon, from epitaxial liftoff techniques, pulling a silicon sheet from a silicon melt, etc.

The base substrate 32 is generally planar, but may also be non-planar. The base substrate 32 can include a textured surface (not shown). The textured surface is useful for reducing reflectivity of the PV cell 30. The textured surface may be of various configurations, such as pyramidal, inverse pyramidal, random pyramidal, isotropic, etc. Texturing can be imparted to the base substrate 32 by various methods. For example, an etching solution can be used for texturing the base substrate 32. The PV cell 30 is not limited to any particular type of texturing process. The base substrate 32, e.g. wafer, can be of various thicknesses, such as from about 1 to about 1000, about 75 to about 750, about 75 to about 300, about 100 to about 300, or about 150 to about 200, μm thick on average.

The base substrate 32 is typically classified as a p-type or an n-type, silicon substrate (based on doping). In certain embodiments, the base substrate 32 includes an upper (or front side) doped region 34, which is generally the sun up/facing side. The upper doped region 34 may also be referred to in the art as a surface emitter, or active semiconductor, layer. In certain embodiments, the upper doped region 34 of the base substrate 32 is an n-type doped region (i.e., an n⁺ emitter layer) such that a remainder of the base substrate 32 is generally p-type. In other embodiments, the upper doped region 34 of the base substrate 32 is a p-type doped region (i.e., a p⁺ emitter layer) such that a remainder of the base substrate 32 is generally n-type. The upper doped region 34 can be of various thicknesses, such as from about 0.1 to about 5, about 0.3 to about 3, or about 0.4, μm thick on average. The upper doped region 34 may be applied such that doping under the fingers 40a (described below) is increased, such as in “selective emitter” technologies.

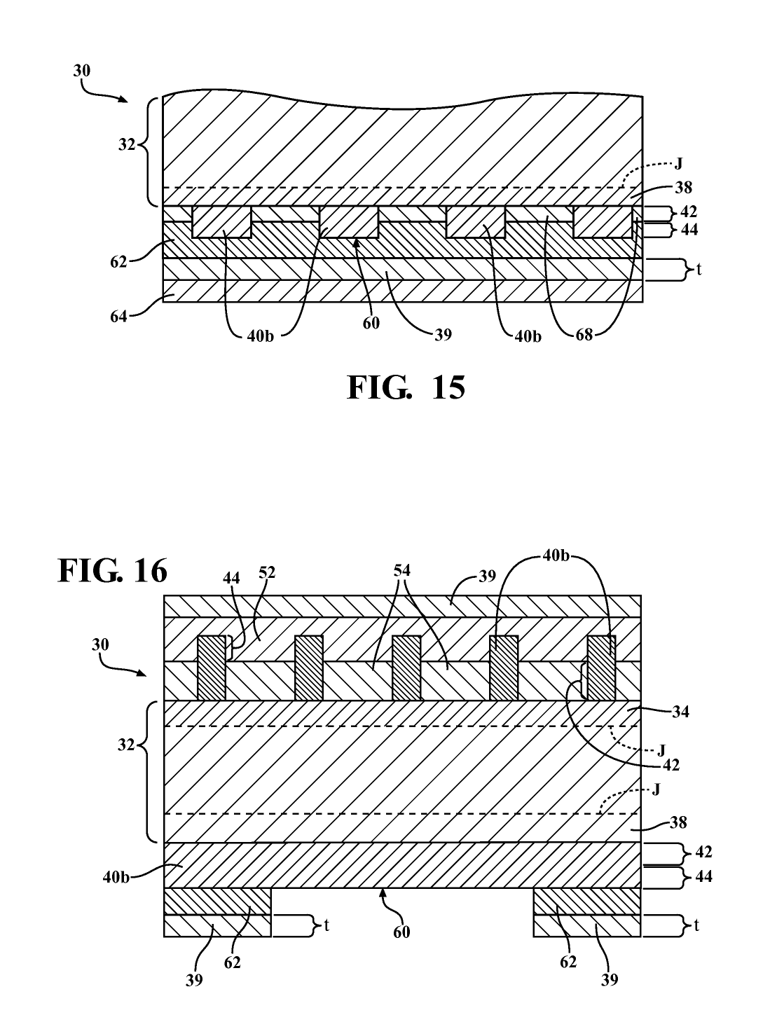

Referring to FIGS. 12 through 15, the base substrate 32 can include the rear doped region 38. The base substrate 32 can also include the rear doped region 38 opposite the upper doped region 34 (if present), as best shown in FIGS. 16 through 20. The rear doped region 38 may also be referred to as a rear side doped region 38. In certain embodiments, the rear doped region 38 may also be referred to in the art as a back surface field (BSF). Typically, one of the doped regions, e.g. the upper 34, is an n-type and the other doped region, e.g. the rear 38, is a p-type. The opposite arrangement may also be used, i.e., the upper 34 is a p-type and the rear 38, is an n-type. Such configurations, where the oppositely doped region 34, 38 interfaces, are referred to in the art as p-n junctions (J) and are useful for photo-excited charge separation provided there is at least one positive (p) region and one negative (n) region. Specifically, when two regions of different doping are adjacent, a boundary defined there between is generally referred to in the art as a junction. When the doping are of opposite polarities then the junction (J) is generally referred to as a p-n junction (J). When doping is merely of different concentrations, the “boundary” may be referred to as an interface, such as an interface between like regions, e.g. p and p⁺ regions. As shown generally in the Figures, such junctions (J) may be optional, depending on what type of doping is utilized in the base substrate 32. The PV cell 30 is not limited to any particular number or location of junction(s) (J). For example, the PV cell 30 may only include one junction (J), such as on the front or rear.

Various types of dopants and doping methods can be utilized to form the doped regions 34, 38 of the base substrate 32. For example, a diffusion furnace can be used to form an n-type doped region 34, 38 and a resulting n-p (or “p-n”) junction (J). An example of a suitable gas is phosphoryl chloride (POCl₃). In addition or alternate to phosphorus, arsenic can also be used to form n-type regions 34, 38. At least one of the periodic table elements from group V, e.g. boron or gallium, can be used to form p-type regions 34, 38. The PV cell 30 is not limited to any particular type of dopant or doping process.

Doping of the base substrate 32 can be at various concentrations. For example, the base substrate 32 can be doped at different dopant concentrations to achieve resistivity of from about 0.5 to about 10, about 0.75 to about 3, or about 1, Ω·cm (Ω·cm). The upper doped region 34 can be doped at different dopant concentrations to achieve sheet resistivity of from about 50 to about 150, or about 75 to about 125, or about 100, Ω/□ (Ω per square). In general, a higher concentration of doping may lead to a higher open-circuit voltage (V_{OC}) and lower resistance, but higher concentrations of doping can also result in charge recombination depleting cell performance and introduce defect regions in the crystal.

In certain embodiments, the collector 40 is a plurality of cylinders arranged as a plurality of dots, a plurality of linear columns, a plurality of non-linear columns, e.g. a columns formed to have a shape of a spiral, a wave, or a snowflake, or combinations thereof. In certain other embodiments, as particularly illustrated in FIGS. 2 through 9 and 16 through 20, the collector 40 is a plurality of fingers 40a with each finger spaced from each other and with each of the fingers 40a having a lower portion in electrical contact with the upper doped region 34 of the base substrate 32. The lower portion 42 of the collector 40, or the lower portion of the fingers 40a if the collector 40 is a plurality of fingers 40a, in actual electrical contact may be quite small, such as tips/ends of the lower portion 42 of the collector 40, or the lower portion of the fingers 40a. Each of the fingers 40a also has an upper portion opposite the lower portion extending away from the upper doped region 34 of the base substrate 32. The fingers 40a are generally disposed in a grid pattern, as best shown in FIGS. 1A and 18 through 20. Typically, the fingers 40a are disposed such that the fingers 40a are relatively narrow while being thick enough to minimize resistive losses. Orientation and number of the fingers 40a may vary. In certain other embodiments, the collector 40 is disposed on the doped region 34, 38 of the base substrate 32 such that the PV cell 30 comprises a bifacial solar cell as understood in the art.

The fingers 40a can be of various widths, such as from about 10 to about 200, about 70 to about 150, about 90 to about 120, or about 100, μm wide on average. The fingers 40a can be spaced various distances apart from each other, such as from about 1 to about 5, about 2 to about 4, or about 2.5, mm apart on average. The fingers 40a can be of various thicknesses, such as from about 5 to about 50, about 5 to about 25, or about 10 to about 20, μm thick on average.

In certain embodiments, each of the fingers 40a comprises a first metal, which is present in each of the fingers 40a in a majority amount. The first metal may comprise various types of metals. In certain embodiments, the first metal comprises silver (Ag). In other embodiments, the first metal comprises copper (Cu). By “majority amount”, it is generally meant that the first metal is the primary component of the fingers 40a, such that it is present in an amount greater than any other component that may also be present in the fingers 40a. In certain embodiments, such a majority amount of the first metal, e.g. Ag, is generally greater than about 35, greater than about 45, or greater than about 50, percent by weight (wt %), each based on the total weight (btw) of the finger 40a.

The fingers 40a can be formed by various methods. Suitable methods include sputtering; vapor deposition; strip or patch coating; ink-jet printing, screen printing, gravure printing, letter printing, thermal printing, dispensing or transfer printing; stamping; electroplating; electroless plating; or combinations thereof. One type of method is generally referred to as an etching/firing process. Other compositions for forming the fingers 40a are described further below.

In certain embodiments, the fingers 40a are formed by a plating process (rather than an etching/firing process). In these embodiments, the fingers 40a generally comprise a plated or stacked structure (not shown). For example, the fingers 40a can comprise two or more of the following layers: nickel (Ni), Ag, Cu, and/or tin (Sn). The layers can be in various orders, provided the Cu layer (if present) is not in direct physical contact with the upper doped region 34 of the base substrate 32. Typically, a seed layer comprising Ag or a metal other than Cu, e.g. Ni, is in contact with the upper doped region 34. In certain embodiments, the seed layer comprises Ni silicide. Subsequent layers are then disposed on the seed layer to form the fingers 40a. When the fingers 40a include Cu, a finger passivation layer such as Sn or Ag is disposed over the Cu layer to prevent oxidation. In certain embodiments, the lower portions 48 of the fingers 40a comprise Ni, the upper portions 50 of the fingers 40a comprise Sn, and Cu is disposed between the Ni and Sn. In this way, the Cu is protected from oxidation by the Ni and Sn and as described in an embodiment below, also a passivation layer 54. Such layers can be formed by various methods, such as aerosol printing and firing; electrochemical deposition; etc. The PV cell 30 is not limited to any particular type of process of forming the fingers 40a.

As best shown in FIGS. 2 through 5, the electrically conductive layer 39, which is described in greater detail below, can be disposed on and in physical contact with the upper portion 44 of the collector 40 and also in physical contact with the upper doped region 34 of the base substrate 32.

As understood in the art, isotropic electrically conductive layers have the same electrical conductivity along all axes, i.e., the electrical conductivity of isotropic electrically conductive layers is not directionally dependent. Alternatively, the electrical conductivity of anisotropic electrically conductive layers is directionally dependent and may vary when measured along different axes.

The electrically conductive layer 39, which is formed from an electrically conductive composition, is either electrically isotropic or anisotropic as described in greater detail below. The electrically conductive layer 39 comprises a binder and electrically conductive particles comprising at least one metal selected from Group 8 through Group 14 metals. In one embodiment, the electrically conductive layer 39 is an electrically conductive adhesive layer

In certain embodiments, the binder is characterized as a paste, a thermoplastic film, an adhesive, or a pressure-sensitive adhesive (PSA).

Generally, an adhesive is any material that will usefully hold two objects together solely by surface contact, whereas a PSA will adhere to a variety of surfaces with light hand pressure. Adhesion typically results from attractive molecular forces know as Van der Waal's forces, which arise when two objects are brought in intimate contact. Typically, an adhesive must wet-out an object's surface, which means that the adhesive requires the characteristics of a liquid. Therefore, commercial adhesives are typically carried in a solvent or are flowable at room temperature. Alternatively, a thermoplastic film, which becomes molten and flows when heated may be used.

However, when in use, the adhesive requires the properties of a solid to resist applied forces that may break the bond formed between the object to which it was applied. This is achieved by either a physical or chemical change in the adhesive brought about by solvent evaporation, chemical cross-linking, or cooling when a thermoplastic film returns to its solid state at room temperature. These changes result in stress developing in the adhesive joint.

The one adhesive system that is an exception to that which is described above is the PSA, which functions without the need for either a physical or chemical change to take place. A PSA allows for enough deformability and wettability to achieve intimate contact, yet enough internal strength or cohesion to resist moderate separation forces. This bond is typically stress free and therefore does not require curing, as the PSA lies between a viscous and rubbery state. However, because properties may be temperature dependent, some PSAs can be formulated to cure if exposed to elevated temperatures to improve cohesive strength. The adhesive properties of PSAs can be characterized to determine the level of tack, peel and shear strength using various ASTM methods including, but not limited to, ASTM D2979 (probe tack), ASTM D3121 (rolling ball tack), D1876 (t-peel), D903 (180° peel), D1002 (lap shear).

The binder can comprise various types of monomers, prepolymers, polymers, or combinations thereof. In certain embodiments, the binder is selected from the group of organic compositions, silicone compositions, or combinations thereof. In one embodiment, the binder is an acrylic composition. In another embodiment, the binder is an epoxy composition. In yet another embodiment, the binder is a silicone composition as also provided in the electrically conductive silicone composition of the present invention. In this embodiment, the silicone composition can comprise an organopolysiloxane. In certain other embodiments the binder is a silicone composition comprising an organopolysiloxane and is free of, or substantially free of, organic compositions (e.g. polymers, copolymers, and/or monomers) including, but not limited to, acrylic compositions, ethylene vinyl acetate compositions, epoxy compositions, and urethane compositions. Accordingly, it is to be appreciated that in certain embodiments the electrically conductive composition and the electrically conductive layer 39 formed therefrom are free of, or substantially free of, organic compositions including, but not limited to, acrylic compositions, ethylene vinyl acetate compositions, epoxy compositions, and urethane compositions.

The terminology “substantially free”, as used herein in reference to the organic compositions, refers to a sufficiently low amount of organic compositions including, but not limited to, acrylic compositions, ethylene vinyl acetate compositions, epoxy compositions, and urethane compositions. In this embodiment, the amount of organic compositions that are present in the binder is typically less than 5, alternatively less than 1, alternatively less than 0.5, alternatively less than 0.1, and alternatively zero, wt %, each btw of the binder.

In certain embodiments, the organopolysiloxane is a condensation curable organopolysiloxane or the cured product thereof. In another embodiment, the organopolysiloxane is a hydrosilylation curable organopolysiloxane or the cured product thereof. In yet another embodiment, the organopolysiloxane is a peroxide curable organopolysiloxane or the cured product thereof. Specific suitable examples of organopolysiloxanes are disclosed in U.S. Pat. No. 5,776,614 (Cifuentes), U.S. Pat. No. 6,337,086 (Kanios), and International Pub. No. WO2007/050580 (Mitchell), which are hereby incorporated by reference in their entirety to the extent they do not conflict with the general scope of this invention.

In certain other embodiments, the organopolysiloxane includes a linear organopolysiloxane component, a resinous component, or combinations thereof. In this embodiment, the organopolysiloxane typically includes the resinous component in an amount of from about 40 to about 70 wt %, and the linear organopolysiloxane component in an amount of from about 30 to about 60 wt %, each btw of the organopolysiloxane. Alternatively, the organopolysiloxane includes the resinous component in an amount of from about 50 to about 65 wt %, and the linear organopolysiloxane component in an amount of from about 35 to about 50 wt %, each btw of the organopolysiloxane.

Typically, the resinous component includes silicon-bonded hydroxyl groups in amounts which typically range from about 1 to about 4 weight percent of silicon-bonded hydroxyl groups and comprise triorganosiloxy units of the formula R₃SiO_{1/2} and tetrafunctional siloxy units of the formula SiO_{4/2} in a mole ratio of from about 0.6 to about 0.9 R₃SiO_{1/2} units for each SiO_{4/2} unit present. Blends of two or more such resinous components may also be used. Typically, there is at least some, alternatively at least about 0.5 weight percent, silicon-bonded hydroxyl groups to enable the linear organopolysiloxane component to copolymerize with the resinous component and/or to react with an endblocking agent which can be added to chemically treat the organopolysiloxane. The resinous component is generally benzene-soluble, is typically solid at room temperature, and can be in solution in an organic solvent. Suitable examples of organic solvents include, but are not limited to, benzene, toluene, xylene, methylene chloride, perchloroethylene, naphtha mineral spirits, other hydrocarbons having from 1 to 30 carbon atoms, and mixtures thereof.

In one embodiment, the resinous component consists essentially of from about 0.6 to about 0.9 R₃SiO_{1/2} units for every SiO_{4/2} unit in the copolymer. It is to be appreciated that R₂SiO units may be present in small amounts, i.e., a few mole percent, depending on the ultimate product desired. Each R denotes, independently, a monovalent hydrocarbon group having from 1 to 6 inclusive carbon atoms such as methyl, ethyl, propyl, isopropyl, hexyl, cyclohexyl, vinyl, allyl, propenyl and phenyl. Typically, the R₃SiO_{1/2} units are Me₃SiO_{1/2} units and/or Me₂R¹SiO_{1/2} units wherein R¹ is a vinyl (“Vi”) or phenyl (“Ph”) group. In one embodiment, no more than 10 mole percent of the R₃SiO_{1/2} units present in the resinous component are Me₂R²SiO_{1/2} units and the remaining units are Me₃SiO_{1/2} units where each R² is a vinyl group. In another embodiment, the R₃SiO_{1/2} units are Me₃SiO_{1/2} units.

The mole ratio of R₃SiO_{1/2} and SiO_{4/2} units can be determined simply from a knowledge of the identity of R in the R₃SiO_{1/2} units and the percent carbon analysis of the resinous component. Typically, the resinous component consists of from 0.6 to 0.9 Me₃SiO_{1/2} units for every SiO_{4/2} unit and has a value determined by carbon analysis of from about 19.8 to about 24.4 wt %. In one embodiment, the resinous component is a trimethylsiloxy and hydroxyl end-blocked MQ resin. In another embodiment, the resinous component is a bodied MQ resin.

The resinous component may be prepared according to Daudt et al., U.S. Pat. No. 2,676,182 (issued Apr. 20, 1954 and hereby incorporated by reference in its entirety to the extent it does not conflict with the general scope of this invention) whereby a silica hydrosol is treated at a low pH with a source of R₃SiO_{1/2} units such as a hexaorganodisiloxane such as Me₃SiOSiMe₃, ViMe₂SiOSiMe₂Vi, or MeViPhSiOSiPhViMe, or a triorganosilane such as Me₃SiCl, Me₂ViSiCl, or MeViPhSiCl. Such resinous components are typically made such that the resinous component contains from about 1 to about 4 weight percent of silicon-bonded hydroxyl groups. Alternatively, a mixture of suitable hydrolyzable silanes free of R may be cohydrolyzed and condensed. In this embodiment, the product of the cohydrolysis and condensation is typically treated with a suitable silylating agent, such as hexamethyldisilazane or divinyltetramethyldisilazane, to reduce the silicon-bonded hydroxyl content of the product to less that about 1 wt %. However, it is to be appreciated that treatment with a silylating agent is not required. Typically, the resinous component utilized contains from about 1 to 4 weight percent of silicon-bonded hydroxyl groups.

The linear organopolysiloxane component typically comprises one or more polydiorganosiloxanes comprising ARSiO units terminated with endblocking TRASiO_{1/2} units. Each of the polydiorganosiloxanes typically has a viscosity of from about 100 to about 30,000,000, centipoise (cp) at 25° C. (100 millipascal-seconds (mPa·s) to 30,000 pascal seconds (Pa·s) where 1 cp equals 1 mPa·s). As is well-known, viscosity is directly related to the average number of diorganosiloxane units present for a series of polydiorganosiloxanes of varying molecular weights which have the same endblocking units. Polydiorganosiloxanes having a viscosity of from about 100 to about 100,000 cp at 25° C. range from fluids to somewhat viscous polymers. These polydiorganosiloxanes are typically prereacted with the resinous component prior to condensation in the presence of the endblocking agent to improve the tack and adhesion properties of the resulting organopolysiloxane as will be further described. Polydiorganosiloxanes having viscosities in excess of about 100,000 cp can typically be subjected to condensation/endblocking without prereaction. Polydiorganosiloxanes having viscosities in excess of about 1,000,000 cp are highly viscous products often referred to as gums and the viscosity is often expressed in terms of a Williams Plasticity value (polydimethylsiloxane gums of about 10,000,000 cp viscosity typically have a Williams Plasticity Value of about 50 mils (1.27 mm) or more at 25° C.).

In one embodiment, the linear organopolysiloxane component consists essentially of one or more polydiorganosiloxanes having ARSiO units where each R is as defined above. Each A is selected from R or halohydro-carbon groups of from 1 to 6 inclusive carbon atoms such as chloromethyl, chloropropyl, 1-chloro-2-methylpropyl, 3,3,3-trifluoropropyl and F₃C(CH₂)₅ groups. Thus the polydiorganosiloxane can contain Me₂SiO units, PhMeSiO units, MeViSiO units, Ph₂SiO units, methylethylsiloxy units, 3,3,3-trifluoropropyl units and 1-chloro, 2-methylpropyl units and the like. Typically, the ARSiO units are selected from the group consisting of R₂SiORR′SiO units, Ph₂SiO units, and combinations of both where R and R′ are as above, at least 50 mole percent of R′ present in the linear organopolysiloxane component is methyl groups and no more than 50 mole percent of the total moles of ARSiO units present in the linear organopolysiloxane component are Ph₂SiO units. Alternatively, no more than 10 mole percent of the ARSiO units present in the linear organopolysiloxane component are MeRSiO units where R is as above defined and the remaining ARSiO units present are Me₂SiO units. Alternatively, all or substantially all of the ARSiO units are Me₂SiO units.

The linear organopolysiloxane component is typically terminated with endblocking units of the unit formula TRASiO_{1/2} where R and A are as defined above and each T is R, OH, H or OR′ groups where each R′ is an alkyl group of from 1 to 4 inclusive carbon atoms such as methyl, ethyl, n-propyl, and isobutyl groups. H, OH and OR′ provide a site for reaction with endblocking triorganosilyl units of the endblocking agent and also provide a site for condensation with other such groups on the linear organopolysiloxane component or with the silicon-bonded hydroxyl groups present in the resinous component. Typically, T is OH and the linear organopolysiloxane component can readily copolymerize with the resinous component. Polydiorganosiloxanes terminating with triorganosiloxy (e.g. R₃SiO_{1/2} such as (CH₃)₃SiO_{1/2} or CH₂CH(CH₃)₂SiO_{1/2}) units can also be utilized when an appropriate catalyst is present. More specifically, when the condensation reaction is conducted with heating some of the triorganosiloxy units will be cleaved. The cleavage exposes a silicon-bonded hydroxyl group which can then condense with silicon-bonded hydroxyl groups in the resinous component or with other polydiorganosiloxanes containing H, OH or OR′ groups or silicon-bonded hydroxyl groups exposed by cleavage reactions. Examples of suitable catalysts include, but are not limited to, HCl and ammonia which can be generated when chlorosilanes and organosilazanes are used as endblocking agents, respectively. Mixtures of polydiorganosiloxanes containing different substituent groups may also be used. A suitable example of the linear organopolysiloxane component includes, but is not limited to, an end-blocked polydimethylsiloxane including a hydroxyl end-blocked polydimethylsiloxane.

Methods for the manufacture of the linear organopolysiloxane component are well known as exemplified by the following U.S. Pat. No. 2,490,357 (Hyde); U.S. Pat. No. 2,542,334 (Hyde); U.S. Pat. No. 2,927,907 (Polmanteer); U.S. Pat. No. 3,002,951 (Johannson); U.S. Pat. No. 3,161,614 (Brown, et al.); U.S. Pat. No. 3,186,967 (Nitzche, et al.); U.S. Pat. No. 3,509,191 (Atwell) and U.S. Pat. No. 3,697,473 (Polmanteer, et al.) which are hereby incorporated by reference in their entirety to the extent they do not conflict with the general scope of this invention.

In one embodiment, the organopolysiloxane is a PSA. To obtain PSAs which are to be cured by peroxide or through aliphatically unsaturated groups present in the resinous component or the linear organopolysiloxane component, if the resinous component contains aliphatically unsaturated groups, then the linear organopolysiloxane component should be free of such groups and vice-versa. If both components contain aliphatically unsaturated groups, curing through such groups can result in products which do not act as PSAs.

The PSA typically has a well defined silanol concentration in a range of between about 8,000 and about 13,000 ppm as determined via Fourier transform infrared spectroscopy or 29Si NMR spectroscopy. This can be accomplished by treating the PSA with an agent which reacts with silanol or it can be accomplished by blending the PSA with another silicone PSA which has a lower silanol content, such as those disclosed in U.S. Pat. No. RE35,474.

If the silanol content is reduced by chemically treating the PSA, this can be accomplished by treating the resinous component, by treating the linear organopolysiloxane component, by treating both the resinous component and the linear organopolysiloxane component, and/or by treating a mixture of the resinous component and the linear organopolysiloxane component.

The chemical treatment is typically accomplished by conducting the condensation of the resinous component and the linear organopolysiloxane component in the presence of at least one organosilicon endblocking agent capable of generating endblocking triorganosilyl units. Examples of these endblocking agents are set forth in U.S. Pat. No. 4,591,622 and U.S. Reissue Pat. RE35,474 which are incorporated by reference in their entirety to the extent they do not conflict with the general scope of this invention.

Endblocking agents capable of providing endblocking triorganosilyl units are commonly utilized as silylating agents and a wide variety of such agents are known. A single endblocking agent such as hexamethyldisilazane can be utilized or a mixture of such agents such as hexamethyldisilazane and tetramethyldivinyldisilazane can be utilized to vary the physical properties of the PSA. For example, use of an endblocking agent containing fluorinated triorganosilyl units, such as [(CF₃CH₂CH₂)Me₂Si]₂NH, in the process of the present invention could result in a silicone PSA having improved resistance to hydrocarbon solvents after the film is deposited. Additionally, the presence of the fluorinated triorganosilyl units could affect the tack and adhesion properties of the PSA when R of each of the resinous component and the linear organopolysiloxane component substantially comprises methyl groups. By employing endblocking agents containing higher carbon content silicon-bonded organic groups such as ethyl, propyl or hexyl groups, the compatibility of the PSA with organic PSAs could be improved to allow blending of such adhesives to obtain improved adhesive compositions. Use of endblocking agents having triorganosilyl units having organofunctional groups such as amides, esters, ethers and cyano groups could allow one to change the release properties of the PSA. Likewise, organofunctional groups present in the PSA composition can be altered such as by hydrolyzing ROOCR groups to generate HOOCR-groups which are converted to MOOCR groups where M is a metal cation such as lithium, potassium or sodium. The resulting composition may then exhibit release or other properties different from a composition containing RCOOR-groups.

Use of endblocking agents containing triorganosilyl units with unsaturated organic groups such as vinyl can produce PSAs which can be cross-linked through such groups. For example, an organosilicon cross-linking compound containing silicon-bonded hydrogen can be added along with a noble metal to a PSA composition which contains PhMeViSi- and Me₃Si-endblocking triorganosilyl units to produce a PSA composition which cures via the noble metal catalyzed addition of silicon-bonded hydrogen to silicon-bonded vinyl groups. Use of endblocking agents containing triorganosilyl units with phenyl groups could improve the stability of the PSA to heat. Examples of suitable noble metals include, but are not limited to, platinum (Pt) and rhodium (Rh).

Thus, the endblocking agent serves several purposes. Selection of an appropriate level of endblocking agent enables modification of the properties of the organopolysiloxane without making substantial changes in the resinous component and the linear organopolysiloxane component. Additionally, the molecular weight and thereby the properties of the condensation product of the resinous component and the linear organopolysiloxane component can also be altered since the triorganosilyl units act as endblocking units.

Typically, the appropriate level of endblocking agent is sufficient to provide a silanol concentration in the range of about 8,000 to about 13,000, ppm. The resinous component will typically contain the majority of the silicon-bonded hydroxyl content present in the combination of the resinous component and the linear organopolysiloxane component. Therefore, in certain embodiments, it is desirable to use a resinous component that has a higher silicon-bonded hydroxyl content (e.g. from about 1 to about 4 weight percent) so that more of the triorganosilyl units confining such groups will be reacted into the condensation product of the resinous component and the linear organopolysiloxane component.

Examples of endblocking agents are (Me₃Si)₂NH, (ViMe₂Si)₂NH, (MePhViSi)₂NH, (CF₃CH₂CH₂Me₂Si)₂NH, (Me₃Si)₂NMe, (ClCH₂Me₂Si)₂NH, Me₃SiOMe, Me₃SiOC₂H₅, Ph₃SiOC₂H₅, (C₂H₅)₃SiOC₂H₅, Me₂PhSiOC₂H₅, (i-C₃H₇)₃SiOH, Me₃Si(OC₃H₇), MePhViSiOMe, Me₃SiCl, Me₂ViSiCl, MePhViSiCl, (H₂CCHCH₂)Me₂SiCl, (n-C₃H₇)₃SiCl, (F₃CCF₂CF₂CH₂CH₂)₃SiCl, NCCH₂CH₂Me₂SiCl, (n-C₆H₁₃)₃SiCl, MePh₂SiCl, Me₃SiBr, (t-C₄H₉)Me₂SiCl, CF₃CH₂CH₂Me₂SiCl, (Me₃Si)₂O, (Me₂PhSi)₂O, BrCH₂Me₂SiOSiMe₃, (p-FC₆H₄Me₂Si)₂O, (CH₃COOCH₂Me₂Si)₂O, [(H₂CCCH₃COOCH₂CH₂)Me₂Si]₂O, [(CH₃COOCH₂CH₂CH₂)Me₂Si]₂O, [(C₂H₅OOCCH₂CH₂)Me₂Si]₂O, [(H₂CCHCOOCH₂)Me₂Si]₂O, (Me₃Si)₂S, (Me₃Si)₃N, Me₃SiNHCONHSiMe₃, F₃CH₂CH₂Me₂SiNMeCOCH₃, (Me₃Si)(C₄H₉)NCON(C₂H₅)₂, (Me₃Si)PhNCONHPh, Me₃SiNHMe, Me₃SiN(C₂H₅)₂, Ph₃SiNH₂, Me₃SiNHOCCH₃, Me₃SiOOCCH₃, [(CH₃CONHCH₂CH₂CH₂)Me₂Si]₂O, Me₃SiO(CH₂)₄OSiMe₃, Me₃SiNHOCCH₃, Me₃SiCCH, HO(CH₂)₄Me₂Si₂O, (HOCH₂CH₂OCH₂Me₂Si)₂O, H₂N(CH₂)₃Me₂SiOCH₃, CH₃CH(CH₂NH₂)CH₂Me₂SiOCH₃, C₂H₅NHCH₂CH₂S(CH₂)₆Me₂SiOC₂H₅, HSCH₂CH₂NH(CH₂)₄Me₂SiOC₂H₅, HOCH₂CH₂SCH₂Me₂SiOCH₃. In one embodiment, the endblocking agent utilized is (Me₃Si)₂NH.

A number of the above endblocking agents generate silanol condensation catalysts including acids such as hydrogen chloride and bases such as ammonia or amines when the triorganosilyl unit reacts with silicon-bonded hydroxyl groups and/or H, OH or OR′ groups present in the resinous component and the linear organopolysiloxane component. Typically condensation involves heating and the presence of a catalyst causing the condensation of the resinous component and the linear organopolysiloxane component to take place at the same time that endblocking by the endblocking triorganosilyl units occurs. Depending on the method of manufacture utilized, the resinous component and/or the linear organopolysiloxane component may contain a sufficient level of residual catalyst to effect condensation and endblocking. Thus, if desired, an additional catalytic amount of a “mild” silanol condensation catalyst can be used where the term “mild” means that it causes the endblocking agent to condense with the resinous component and the linear organopolysiloxane component while causing minimal siloxane bond rearrangement. Examples of “mild” catalysts are those known to be used as curing agents for PSA compositions including amines such as triethylamine and organic compounds such as tetramethylguanidine 2-ethylcaproate, tetramethylguanidine 2-ethylhexanoate and n-hexylamine 2-ethylcaproate. The additional catalyst selected should not cause an excessive amount of cleavage of siloxane bonds in the resinous component and/or the linear organopolysiloxane component during the condensation reaction thereby resulting in gelation or a substantial loss of adhesive properties as is known to happen with organic tin catalysts and strong acids. Typically, the catalyst is only used when no catalyst is provided by endblocking agent. Suitable catalysts and the selection of specific catalyst and amounts thereof for catalyzing the reaction of particular endblocking triorganosilyl units with the silicon-bonded hydroxyl groups found on the organosiloxy units present in the resinous component and the linear organopolysiloxane component are known to those skilled in the art. Use of a catalyst such as HCl generated by a chlorosilane endblocking agent is typical when R₃SiO_{1/2} endblocking units are present in the linear organopolysiloxane component as noted earlier. Silazane endblocking agents can also be used when T is R and alternatively when T in the linear organopolysiloxane component is H. Typically, when T in the linear organopolysiloxane component is OH, an endblocking agent of the silazane type is used such that no extra catalyst needs to be added; the ammonia compound generated is generally volatile and can be eliminated more readily than a nonvolatile, solid catalyst material. When the resinous component is prepared under acidic conditions as described in the Daudt, et al. patent above, there is often a sufficient level of acid catalyst present to enable endblocking units containing Y, selected from alkoxy or OH groups, to be used without any further addition of a condensation catalyst.

When desirable, an effective amount of an organic solvent can be added separately to the mixture of the resinous component (as a solid material or in an organic solvent solution), the linear organopolysiloxane component, the endblocking agent, and the catalyst to reduce the viscosity thereof or else can be present as a result of the fact that the resinous component and/or the linear organopolysiloxane component was added as a portion of a solution including the organic solvent. The organic solvent should be inert towards the other components of the mixture and not react with them during the condensation step. As noted earlier, the resinous component is often prepared as a solution including toluene and/or xylene. Use of an organic solvent is often necessary when the linear organopolysiloxane component is in the form of a high viscosity gum which results in a high viscosity mixture even when the mixture is heated to typical processing temperatures of from about 100 to about 150, ° C. In one embodiment, the organic solvent permits azeotropic removal of water. In certain embodiments, the organic solvent functions as a solvent. In certain other embodiments, the organic solvent functions as a vehicle, e.g. a dispersant. In still other embodiments, the organic solvent functions both as a solvent and as a vehicle.

The term “organic solvent” includes a single solvent such as benzene, toluene, xylene, trichloroethylene, perchloroethylene, ketones, halogenated hydrocarbons such as dichlorodifluoromethane, naphtha mineral spirits, hydrocarbons having from 1 to 30 carbon atoms, and mixtures of two or more organic solvents to form a blended organic solvent. In one embodiment, a ketone such as methylisobutyl ketone is used as at least a portion of the solvent when fluorinated groups are present on a major amount of the siloxane or silyl units present in the linear organopolysiloxane component for compatibility reasons. Typically, the mixture contains a hydrocarbon solvent selected from the group consisting of benzene, toluene and xylene.

In another embodiment, the organic solvent is a catalytic solvent. The catalytic solvent is selected from the group consisting of carboxylic acids having at least six carbon atoms and having a boiling point of at least 200° C. and amines having at least 9 carbon atoms and having a boiling point of at least 200° C. The term “boiling point” denotes the boiling point of a liquid at 760 mm of Hg. Examples of suitable carboxylic acids include, but are not limited to, nonanoic acid, caproic acid, caprylic acid, oleic acid, linoleic acid, linolenic acid, and N-coco-beta-aminobutyric acid. Examples of suitable amines include, but are not limited to, dodecylamine, hexadecylamine, octadecylamine, dimethyldodecylamine, dicocoamine, methyldicocoamine, dimethyl cocoamine, dimethyltetradecylamine, dimethylhexadecylamine, dimethyloctadecylamine, dimethyl tallow amine, dimethylsoyaamine, dimethyl nonylamine, di(hydrogenated-tallow)amine, and methyldi(hydrogenated-tallow)amine. In still another embodiment, the catalyst is a combination of two or more different carboxylic acids as described above, a combination of two or more different amines as described above, or a combination of a carboxylic acid as described above and an amine as described above. The carboxylic acids and amines described above act both as a catalyst and as a solvent (i.e. they perform dual function) thus eliminating the need for employing a silanol condensation catalyst.

Typically, the resinous component and the linear organopolysiloxane component are mixed together with the organic solvent, if the organic solvent is added. The condensation reaction may take place at room temperature if a suitably reactive silylating agent, a suitable catalyst, or the catalytic solvent is added. Alternatively, the condensation reaction includes heating at about 100 to about 120, ° C. A suitable example of the reactive silylating agent includes, but is not limited to, a silazane, e.g. hexamethyldisilazane. A suitable example of the catalyst includes, but is not limited to, tetramethylguanidine 2-ethylhexanoate. Thus, the method typically involves mixing the resinous component, the linear organopolysiloxane component, and the organic solvent until the mixture is uniform followed by the addition of the endblocking agent and, then any condensation catalyst for the endblocking reaction. The method may further include the step of vacuum stripping of any condensation by-products if present.

Condensation is begun when addition of a suitably reactive endblocking agent such as a silazane or a catalyst is made if the reaction is to take place at room temperature or else begins when the mixture is heated from about 80 to about 160 and alternatively from about 100 to about 120, ° C. Condensation is typically allowed to proceed at least until the rate of evolution of condensation byproducts such as water is substantially constant. Heating is then continued until the desired physical properties such as viscosity, tack and adhesion values are obtained. Typically, the mixture is allowed to reflux for an additional 1 to 4 hours after the rate of evolution of condensation by-products is substantially constant. Longer condensation times may be needed for compositions containing organofunctional groups such as fluorinated groups on the linear organopolysiloxane component and/or endblocking agents which are less compatible with those present on the resinous component.

When the condensation reaction is complete, the residual endblocking agent is solvent stripped away by removing excess solvent during or after the azeotropic removal of condensation by-products. The nonvolatile solids content of the resulting PSA can be adjusted by adding or removing solvent, the solvent present can be completely removed and a different organic solvent added to the PSA, the solvent can be removed completely if the condensation product is sufficiently low in viscosity or else the mixture can be recovered and used as is. In one embodiment, the PSA is a solution including the organic solvent in an amount of from about 30 to about 70 weight percent of the total mixture of the resinous component, the linear organopolysiloxane component, the endblocking agent, the catalyst, and the organic solvent, particularly when the linear organopolysiloxane component has a viscosity of greater than about 100,000 cp at 25° C.

It is to be appreciated that the silicone composition of the binder and/or the electrically conductive silicone composition can include organopolysiloxanes and components thereof which are not cured/crosslinked, organopolysiloxanes and the components thereof which are cured/crosslinked, or combinations thereof. Stated differently, the resinous component and the linear organopolysiloxane component of the organopolysiloxane are not required to crosslink with one another.

Typically, the organopolysiloxane of the silicone composition has a number average molecular weight (Mₙ) of from about 100 to about 500,000, alternatively from about 10,000 to about 500,000 g/mol, alternatively from about 100,000 to about 300,000, alternatively from about 100 to about 10,000, and alternatively from about 1,000 to about 5,000, g/mol to provide the organopolysiloxane of this embodiment with sufficient physical properties. Mₙ is typically determined by Gel Permeation Chromatography (GPC) wherein the organopolysiloxane is prepared in toluene and analyzed against polystyrene standards using refractive index detection. In one embodiment, the silicone composition includes a blend of at least two organopolysiloxanes wherein a first organopolysiloxane has a Mₙ of from about 10,000 to about 500,000 g/mol and alternatively from about 100,000 to about 300,000 and a second organopolysiloxane has a Mₙ of from about 100 to about 10,000 and alternatively from about 1,000 to about 5,000, g/mol.

Additionally, the organopolysiloxane typically has a glass transition temperature, T_{g}, of from about −150 to about −100 and alternatively from about −125 to about −100, ° C. The Tg is determined by Differential Scanning calorimetry (DSC) wherein the organopolysiloxane is cooled to about −150° C., then heated to 200° C. at a rate of 10° C./min. In another embodiment, the organopolysiloxane has a dynamic viscosity of from about 100 to about 30,000,000, alternatively from about 1,000 to about 10,000,000, alternatively from about 1,000 to about 1,000,000, alternatively from about 1,000 to about 100,000, alternatively from about 5,000 to about 50,000, and alternatively from about 10,000 to about 45,000, cp at 25° C. as determined with a Brookfield® Viscometer, e.g. a Brookfield® Viscometer Model RVT using spindle #5 at 20 rpm. In yet another embodiment, the organopolysiloxane has a specific gravity of from about 0.5 to about 1.5, alternatively from about 0.8 to about 1.2, and alternatively from about 0.9 to about 1.0.

The binder is typically present in the electrically conductive composition in an amount of from about 5 to about 99.9, alternatively from about 5 to about 95, alternatively from about 10 to about 99, alternatively from about 10 to about 90, wt %, each btw of the electrically conductive composition. In one embodiment, where the electrically conductive layer 39 formed from the electrically conductive composition is electrically isotropic, the binder is present in an amount of from about 10 to about 50, alternatively from about 15 to about 30, and alternatively about 20, wt %, each btw of the electrically conductive composition. In another embodiment, where the electrically conductive layer 39 formed from the electrically conductive composition is electrically anisotropic, the binder is present in an amount of from about 50 to about 99.5, alternatively from about 90 to about 97, wt %, each btw of the electrically conductive composition.

In another embodiment, the binder comprises a dispersion having a solids content of from about 45 to about 65, alternatively from about 50 to about 60, and alternatively from about 55 to about 60, wt %, each btw of the electrically conductive composition. In yet another embodiment, the binder comprises a dispersion having a solids content of from about 1 to about 45, alternatively from about 3 to about 40, and alternatively from about 12 to about 30, wt %, each btw of the electrically conductive composition. In these embodiments, the electrically conductive composition includes a solvent comprising a hydrocarbon having from 1 to 30 carbon atoms as described in greater detail below.

Suitable examples of silicone compositions include pressure sensitive adhesives commercially available from Dow Chemical of Midland, Mich., under the tradenames Dow Corning® 7358 Adhesive and Dow Corning® Q2-7566 Adhesive.

The binder generally functions to improve the adherence of the electrically conductive layer 39 to a substrate, and increases overall cohesive strength of the electrically conductive layer 39. The binder also acts as a carrier for the at least one metal selected from Group 8 through Group 14 metals which is described in greater detail further below.

The electrically conductive particles comprises at least one metal selected from the group of Group 8 through Group 14 metals of the Periodic Table of Elements (version date Jan. 21, 2011). Typically, the metal has a melting temperature that is greater than about 200, alternatively greater than about 700, alternatively greater than about 800, and alternatively greater than about 900, ° C. The metal generally has excellent electrical conductivity. In certain embodiments, the metal comprises at least one metal selected from the group of Cu, gold (Au), Ag, Sn, zinc (Zn), aluminum (Al), Pt, palladium (Pd), Rh, Ni, cobalt (Co), iron (Fe), and/or an alloy of two or more of such metals. Typically, the electrically conductive layer 39 is free of pollutant metals including mercury (Hg), cadmium (Cd), lead (Pb), and chromium (Cr). By “free of”, it is generally meant that the composition, or a component thereof, does not include such metals. For example, the composition is typically free of solder powders comprising Pb. In some embodiments, there may be trace amounts of such metals.

In certain embodiments, the metal comprises Ag, an alloy comprising Ag, or is Ag powder. Various types of Ag powder can be utilized as the metal. For example, Ag powder may include a surface treatment including a stability enhancer or surface protectant such as an organic chelation agent. The metal can be of various sizes. In one embodiment, wherein the electrically conductive layer 39 is electrically isotropic, the electrically conductive particles comprise metal flakes having a particle size of from about 0.1 to about 25, alternatively from about 1 to about 25, and alternatively from about 5 to about 15, μm on average. In another embodiment, wherein the electrically conductive layer 39 is electrically anisotropic, the electrically conductive particles are disposed on a carrier particle. Various types of carrier particles can be utilized. Examples of suitable carrier particles include glass beads and glass rods, e.g. Ag coated glass beads or rods. In this embodiment, the carrier particle including the metal has a particle size of from about 0.1 μm to about the thickness (t) of the electrically conductive layer 39.

The electrically conductive particles are typically present in the electrically conductive composition in an amount of from about 0.1 to about 95, alternatively from about 1 to about 95, alternatively from about 60 to about 80, alternatively from about 60 to about 70, and alternatively from about 65 to about 75, wt %, each btw of the electrically conductive composition. In one embodiment, where the electrically conductive layer 39 formed from the electrically conductive composition is electrically isotropic, the electrically conductive particles are present in an amount of from about 40 to about 90, alternatively from about 50 to about 90, alternatively from about 65 to about 90, and alternatively from about 75 to about 85, wt %, each btw of the electrically conductive composition. In another embodiment, where the electrically conductive layer 39 formed from the electrically conductive composition is electrically anisotropic, the electrically conductive particles are present in an amount of from about 0.1 to about 50, alternatively from about 1 to about 15, alternatively from about 3 to about 10, wt %, each btw of the electrically conductive composition.

The electrically conductive composition can include a solvent and/or vehicle. The solvent can be the same as the organic solvent described above or comprise a hydrocarbon having from 1 to 30, alternatively from 5 to 30, and alternatively from 5 to 15, carbon atoms. Typically, the solvent has a high boiling point. In one embodiment, the solvent has a boiling point greater than about 100, alternatively greater than about 110, alternatively greater than about 120, alternatively greater than about 130, alternatively greater than about 140, alternatively greater than about 150, alternatively greater than about 200, ° C. If utilized, the solvent can be useful for cutting the binder into solution or to form a dispersion. The solvent can also be useful for adjusting rheology of the electrically conductive composition. Suitable examples include propylene glycol monomethyl ether acetate (PGMEA) and propylene glycol-1,2 propanediol. These examples of suitable solvents are commercially available from various sources, such as Sigma Aldrich of Chicago, Ill. Another suitable solvent is butyl carbitol, which is commercially available from Dow Chemical. Yet other suitable examples of the solvent include xylene, toluene, and ethylbenzene. Suitable examples of the solvent when the organopolysiloxane is a PSA include alcohols, such as monoterpene alcohol (e.g. terpineol), and benzyl alcohol. The solvent can comprise a combination of at least two or more solvents. The solvent can be used in various amounts. In certain embodiments, the solvent is present in the electrically conductive composition before being removed and forming the electrically conductive layer 39 in an amount of from about 1 to about 65, alternatively from about 1 to about 25, alternatively from about 1 to about 5, alternatively from about 5 to about 10, alternatively from about 15 to about 25, alternatively from about 25 to about 55, alternatively from about 30 to about 50, and alternatively from about 40 to about 45, wt %, each btw of the electrically conductive composition. It is to be appreciated that if present, the solvent is removed, or substantially removed, during formation of the electrically conductive layer 39.

The terminology “substantially removed”, as used herein in reference to the solvent, refers to a sufficiently low amount of the solvent, or products thereof, remaining in the electrically conductive layer 39. Typically, the amount of the solvent that is present in the electrically conductive layer 39 is less than 5, alternatively less than 1, alternatively less than 0.5, alternatively less than 0.1, and alternatively zero, wt %, each btw of the electrically conductive layer 39. It is to be appreciated that the solvent may flash off or may be removed over a period of time by heating the electrically conductive composition at progressively higher temperatures. Without being bound or limited by any particular theory, it is believed that progressively removing the solvent results in improved deposition of the electrically conductive particles, i.e., improved contact among the electrically conductive particles, and/or the electrically conductive layer 39 having improved conductivity. In certain embodiments, the solvent is removed via evaporation at room temperature or upon heating.

In certain embodiments, the electrically conductive composition can further comprise an additive. Various types of additives can be utilized. Examples of suitable additives include adhesion promoters, defoamers, deactivators, anti-oxidants, corrosion inhibitors, thickeners, surface cleaning agents, and/or nano carbon tubes (carbon nanotubes).

If utilized, adhesion promoters are useful for increasing adhesion of the electrically conductive layer 39 on various substrates. Various types of adhesion promoters can be utilized. Examples of suitable adhesion promoters include those based on silane and/or titanate. Employing silane adhesion promoters is useful for increasing adhesion to substrates having organic functionalities. Employing titanate adhesion promoters is useful for increasing adhesion to substrates having inorganic fillers. A combination of different promoters can be used. Examples of suitable adhesion promoters are commercially available from Dow Corning Corp. of Midland, Mich., such as 2-(3,4-epoxycyclohexyl)ethyl]trimethoxysilane, e.g. Silquest A-186; and from Compton Chemical, such as 3-(2,3-epoxypropoxy) propyltrimethoxysilane, e.g. Silquest A-187. Further suitable examples include those commercially available from Kenrich Petrochemicals Co. of Bayonne, N.J., under the trademark Ken-React®, such as Ken-React® KR9S. The adhesion promoter can be used in various amounts. In certain embodiments, the adhesion promoter(s) is present in the electrically conductive composition in an amount of from about 0.01 to about 1, alternatively from about 0.1 to about 1, alternatively from about 0.25 to about 0.75, and alternatively about 0.5, wt %, each btw of the electrically conductive composition.

Typically, the electrically conductive layer 39 has a resistivity from about 1·10⁻⁵ to about 5·10⁻³, alternatively from about 1·10⁻⁵ to about 1·10⁻³, alternatively from about 1·10⁻⁴ to about 1·10⁻³, alternatively from about 1·10⁻⁵ to about 2·10⁻⁴, and alternatively from about 2·10⁻⁴ to about 1·10⁻³, Ohms centimeters (ohm-cm) at 20° C., as measured by a Berger I-V test station configured with a four points probe head or lines resistance probe head. In one embodiment, the electrically conductive layer 39, formed from the electrically conductive silicone composition, has a resistivity from about 1·10⁻⁵ to about 5·10⁻³, alternatively from about 1·10⁻⁵ to about 1·10⁻³, alternatively from about 1·10⁻⁴ to about 1·10⁻³, alternatively from about 1·10⁻⁵ to about 2·10⁻⁴, and alternatively from about 2·10⁻⁴ to about 1·10⁻³, ohm-cm at 20° C., as measured by a Berger I-V test station configured with a four points probe head or lines resistance probe head.

The electrically conductive layer 39 is suitable for electrically connecting multiple PV cells in series. Specifically, the electrically conductive layer 39 is suitable for connecting the PV cell 30 to a ribbon 64, referred to in the art as a “tabbing ribbon” or “interconnect”. In one embodiment, the ribbon 64 is disposed on and in physical contact with the electrically conductive layer 39. In this embodiment, the electrically conductive layer 39 bonds the PV cell 30 and the ribbon 64 together with each the PV cell 30 and the ribbon 64 in direct electrical communication with the electrically conductive layer 39. Accordingly, the ribbon 64 is in indirect electrical communication with the PV cell 30 and can effectively collect current from the PV cell 30. Because the electrically conductive layer 39 bonds the PV cell 30 and ribbon 64 together, the ribbon 64 does not require soldering to the PV cell 30 therefore reducing the number of steps required to form PV cell modules, PV cell assemblies, etc. Additionally, because the ribbon 64 does not require soldering to the PV cell 30, problems frequently associated with soldering are reduced and/or avoided. For example, soldering may cause micro-cracks which can result in defects and/or failures in the PV cell, or in components and/or articles which incorporate the PV cell, such as PV cell modules and PV cell assemblies. Notably, the electrically conductive layer 39 is processed at lower temperatures and dissipates thermal stress more effectively than solder, therefore contributing to improved open circuit voltages. Further, unlike traditional soldered PV cells, the electrically conductive layer 39 can accommodate and connect ribbons of various sizes, whether “narrow” or “thick” as understood in the art, to the PV cell 30. The use of “narrow” ribbons reduces the amount of shading of the PV cell 30 thereby improving performance of the PV cell 30.

In certain embodiments, the PV cell 30 further comprises a passivation layer 54. The passivation layer 54 is useful for increasing sunlight absorption by the PV cell 30, e.g. by reducing reflectivity of the PV cell 30, as well as generally improving wafer lifetime through surface and bulk passivation. The passivation layer 54 has an outer surface 56 opposite the upper doped region 34. The passivation layer 54 may also be referred to in the art as a dielectric passivation, or anti-reflective coating (ARC), layer.

As best shown in FIGS. 4, 5, 8, and 9, the passivation layer 54 is disposed on the upper doped region 34. In this embodiment, the collector 40 is disposed in the passivation layer 54. More specifically, the upper portion 44 of the collector 40 extends through the outer surface 56 of the passivation layer 54. In the embodiment where the collector 40 comprises fingers 40a, the upper portions 50 of the fingers 40a extend through the outer surface 56 of the passivation layer 54. In another embodiment, the passivation layer 54, or an additional passivation layer 68 is disposed on the rear doped region 38 of the base substrate 32 as described in greater detail. In an embodiment where the base substrate 32 includes both an upper doped region 34 and a rear doped region 38, each of the upper doped region 34 and the rear doped region 38 may include a passivation layer 54 disposed thereon. In this embodiment, the passivation layer 54 disposed on the upper doped region 34 is generally referred to as the “passivation layer” whereas the passivation layer 54 disposed on the rear doped region 38 is generally referred to as the “additional passivation layer”.

The passivation layer 54 may be formed from various materials. In certain embodiments, the passivation layer 54 comprises SiOₓ, ZnS, MgFₓ, SiNₓ, SiCNₓ, AlOₓ, TiO₂, a transparent conducting oxide (TCO), or combinations thereof. Examples of suitable TCOs include doped metal oxides, such as tin-doped indium oxide (ITO), aluminum-doped zinc-oxide (AZO), indium-doped cadmium-oxide, fluorine-doped tin oxide (FTO), or combinations thereof. In certain embodiments, the passivation layer 54 comprises SiNₓ. Employing SiNₓ is useful due to its excellent surface passivation qualities. Silicon nitride is also useful for preventing carrier recombination at the surface of the PV cell 30.

The passivation layer 54 may be formed from two or more sub-layers (not shown), such that the passivation layer 54 may also be referred to as a stack. Such sub-layers can include a bottom ARC (B-ARC) layer and/or a top ARC (T-ARC) layer. Such sub-layers can also be referred to as dielectric layers, and be formed from the same or different material. For example, there may be two or more sub-layers of SiNₓ; a sub-layer of SiNₓ and a sub-layer of AlOₓ; etc.

The passivation layer 54 can be formed by various methods. For example, the passivation layer 54 can be formed by using a plasma-enhanced chemical vapor deposition (PECVD) process. In embodiments where the passivation layer 54 comprises SiNₓ, silane, ammonia, and/or other precursors can be used in a PECVD furnace to form the passivation layer 54. The passivation layer 54 can be of various thicknesses, such as from about 10 to about 150, about 50 to about 90, or about 70, nm thick on average. Sufficient thickness can be determined by the refractive indices of the coating material and base substrate 32. The PV cell 30 is not limited to any particular type of coating process.

In certain embodiments, and as best shown in FIGS. 4, 5, and 18, the electrically conductive layer 39 is disposed on and in physical contact with the passivation layer 54 opposite the base substrate 32 such that the base substrate 32 is free of physical contact with the electrically conductive layer 39. In this embodiment, the electrically conductive layer 39 is in physical contact with the upper portion 44 of the collector 40, or the upper portion of the fingers 40a if present, such that the base substrate 32 is in indirect electrical communication with the electrically conductive layer 39 via the collector 40 or fingers 40a. These embodiments also require less material to form the collector 40 than PV cells which do not include passivation layers, thereby reducing overall material costs. In these embodiments, the fingers 40a typically have a thickness of from about 15 to about 50 and alternatively from about 20 to about 50, μm on average. However, it is to be appreciated that the fingers 40a in these embodiments may have any thickness as previously described above.

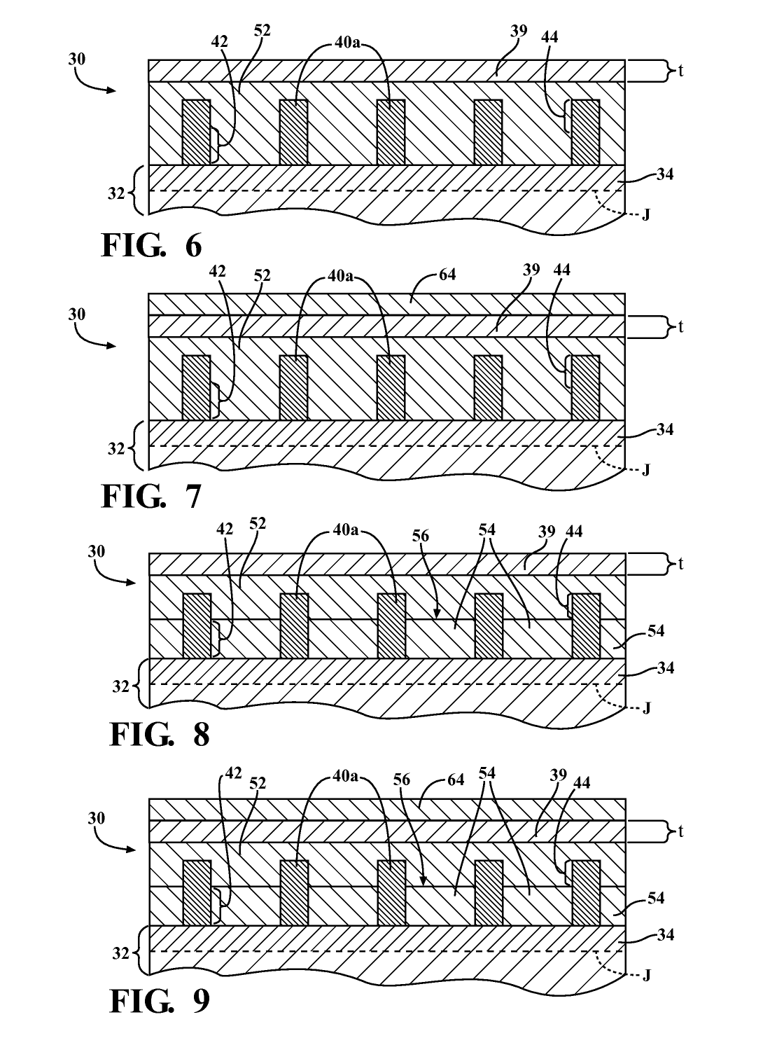

In certain other embodiments, the PV cell 30 further comprises a busbar 52. In one embodiment, the busbar 52 is disposed between the electrically conductive layer 39 and the upper doped region 34 of the base substrate 32 such that the busbar 52 is in physical contact with the upper doped region 34 and the upper portion 44 of the collector 40, or upper portion of the fingers 40a if present, as best shown in FIGS. 6 and 7.

Another embodiment is shown in FIGS. 8 and 9, where the passivation layer 54 is present and the busbar 52 is disposed between the electrically conductive layer 39 and the passivation layer 54 such that the busbar 52 is spaced from the upper doped region 34 of the base substrate 32, i.e., the busbar 52 is spaced from and free of (direct) physical contact with the upper doped region 34 of the base substrate 32. Stated differently, the upper doped region 34 of the base substrate 32 is free of (direct) physical contact with the busbar 52. Specifically, the passivation layer 54 serves as a “barrier” between the busbar 52 and upper doped region 34. As described in greater detail below, it is believed that physical separation of the busbar 52 and the upper doped region 34 is beneficial although not required.

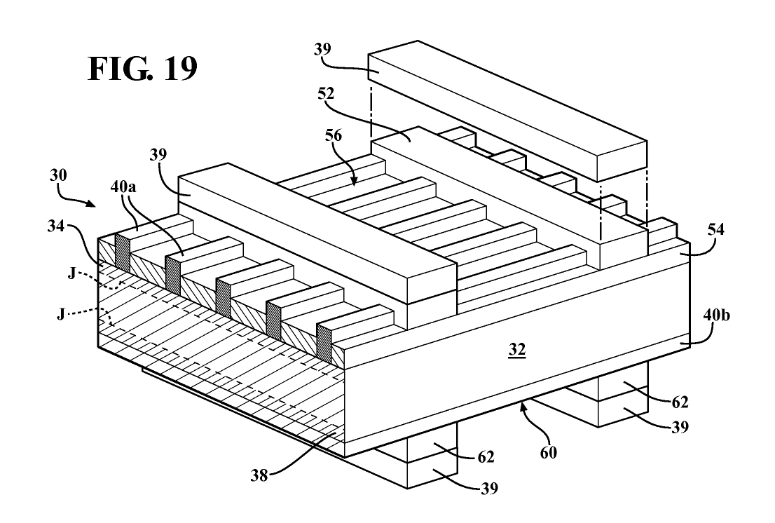

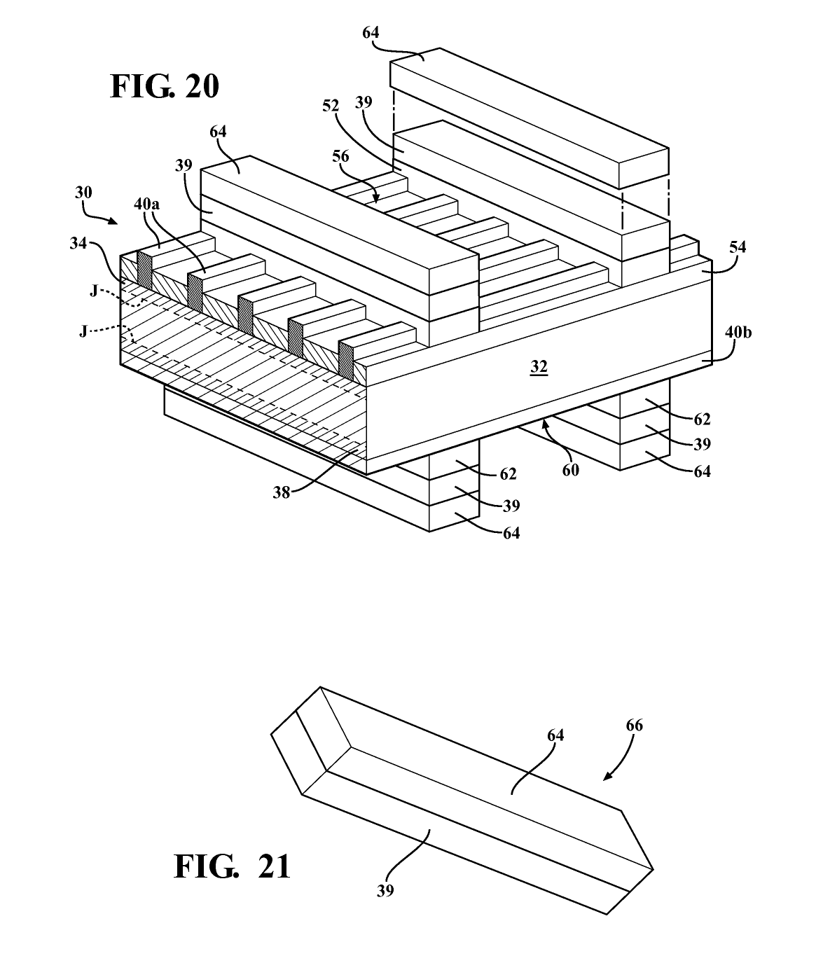

As shown in FIGS. 1A, 19, and 20, the PV cell 30 generally has two busbars 52. In certain embodiments, the PV cell 30 may have more than two busbars 52 (not shown), such as three busbars 52, four busbars 52, six busbars 52, etc. Each busbar 52 is in direct electrical contact with the upper portions 44 of the collector 40, or upper portion of the fingers 40a if present. The busbars 52 are useful for collecting current from the collector 40 which have collected current from the upper doped region 34. As best shown in FIGS. 19 and 20, each of the busbars 52 are disposed around each of the fingers 40a to provide intimate physical and electrical contact to the upper portions 50 of the fingers 40a. Typically, the busbar 52 is transverse the fingers 40a. Said another way, the busbar 52 can be at various angles relative to the fingers 40a, including perpendicular. The upper portion in actual physical/electrical contact may be small, such as just tips/ends of the fingers 40a.

Such contact places the busbar 52 in position for carrying current directly from the fingers 40a. The fingers 40a themselves are in intimate physical and electrical contact with the upper doped region 34 of the base substrate 32.

The busbar 52 can be of various widths, such as from about 0.5 to about 10, about 1 to about 5, or about 2, mm wide on average. The busbar 52 can be of various thicknesses, such as from about 0.1 to about 500, about 10 to about 250, about 30 to about 100 or about 30 to about 50, μm thick on average. The busbars 52 can be spaced various distances apart. Typically, the busbars 52 are spaced to divide lengths of the fingers 40a into ˜equal regions, e.g. as shown in FIG. 1.

In certain embodiments, the busbar 52 comprises a second metal, which is present in the busbar 52 in a majority amount. The “second” is used to differentiate the metal of the busbar 52 from the “first” metal of the collector 40, and does not imply quantity or order. The second metal may comprise various types of metals. In certain embodiments, the second metal of the busbar 52 is the same as the first metal of the fingers 40a. For example, both the first and second metals can be Cu. In other embodiments, the second metal of the busbar 52 is different from the first metal of the fingers 40a. In these embodiments, the first metal typically comprises Ag and the second metal typically comprises Cu. In other embodiments, the second metal comprises Ag. In still other embodiments, the second metal comprises Al. By “majority amount”, it is generally meant that the second metal is the primary component of the busbar 52, such that it is present in an amount greater than any other component that may also be present in the busbar 52. In certain embodiments, such a majority amount of the second metal, e.g. Cu, is generally greater than about 25, greater than about 30, greater than about 35, or greater than about 40, wt %, each btw of the busbar 52.

In certain other embodiments, the busbar 52 also comprises a third metal. The third metal is different from the first metal of the fingers 40a. The third metal is also different from the second metal of the busbar 52. Typically, the metals are different elements, rather than just different oxidation states of the same metal. The “third” is used to differentiate the metal of the busbar 52 from the “first” metal of the fingers 40a, and does not imply quantity or order. The third metal melts at a lower temperature than melting temperatures of the first and second metals. Typically, the third metal has a melting temperature of no greater than about 300, no greater than about 275, or no greater than about 250, ° C. Such temperatures are useful for forming the busbar 52 at low temperatures as described further below.

In certain embodiments, the third metal comprises solder, which may be the same or different from the solder of an electrically conductive busbar composition described in greater detail below. The solder can comprise various metals or alloys thereof. One of these metals is typically Sn, Pb, bismuth (Bi), Cd, Zn, gallium (Ga), indium (In), tellurium (Te), Hg, thallium (Tl), antimony (Sb), selenium (Se) and/or an alloy of two or more of these metals. The third metal can be present in the busbar 52 in various amounts, typically in an amount less than the second metal. The busbar 52 may also comprise a polymer(s) in addition to the second and third metals, as described further below.

In certain embodiments, the busbar 52 is formed from an electrically conductive busbar composition. Specific suitable examples of electrically conductive busbar (or other component) compositions are disclosed in Serial No. PCT/US12/69503, which is hereby incorporated by reference in its entirety to the extent it does not conflict with the general scope of this invention. In further embodiments, the composition consists essentially of, or alternatively consists of, the aforementioned components. In certain embodiments, the composition can further comprise one of more additives, described further below. The composition is useful for forming a conductor. Typically, the conductor is formed by heating the composition, as described further below. The conductor may also be referred to as an electrical conductor, which is electrically conductive. While not limited to a particular configuration or use, the conductor can be in various forms, such as busbars, fingers, pads, dots, and/or other electrode structures. Some of these are described in greater detail hereinafter. The metal powder can comprise various metals. Typically, the metal powder has a melting temperature (or melting point; MP) that is over about 600, over about 700, over about 800, or over about 900, ° C. The metal generally has excellent electrical conductivity. In certain embodiments, the metal powder comprises at least one metal selected from the group of copper (Cu), gold, silver (Ag), zinc, aluminum, platinum, palladium, beryllium, rhodium, nickel, cobalt, iron, molybdenum, tungsten, and/or an alloy of two or more of these metals. In various embodiments, the metal comprises a mixture (or blend) of metal particles (the same as or different from each other), and/or particles comprising two or more different metals. The latter type of particles may be alloys of two or more different metals, and/or coated particles having a core comprising at least one metal and one or more outer layers comprising at least one metal different from the core metal(s). An example of such a coated particle is a silver coated (or plated) copper particle.

In certain embodiments, the composition is substantially to completely free of “heavy” metals. Said another way, the composition typically comprises less than 0.5, less than 0.25, less than 0.1, less than 0.5, approaching zero (0), or 0, weight percent (wt %) heavy metal(s), each based on the total weight of the composition. Examples of heavy metals include mercury, cadmium, lead, and chromium. In certain embodiments, the composition is free of mercury, cadmium, and chromium. In further embodiments, the composition is free of solder powders comprising lead (Pb).

The metal powder may be treated with a stability enhancer and/or surface protectant. Such treatments can include organic chelation agents, such as azoles, e.g. benzotriazole, imidazoles, etc. Generally, decomposition products of such azoles can serve as catalysts for a reaction between the polymer and the carboxylated-polymer to form the conductor from the composition. Such a reaction generally obviates any need for post-curing of the conductor after formation.

In certain embodiments, the metal powder comprises Cu, or is Cu powder. Various types of Cu powder can be utilized. For example, Cu powder may include a surface treatment as described above. The metal powder can be of various sizes. Typically, the metal powder has a particle size of from about 0.05 to about 25, about 5 to about 25, about 5 to about 15, or about 10, μm on average. Various particle size distributions (PSDs) can be utilized, including unimodal, bimodal, or multimodal distributions, with unimodal being typical for fluxing purposes. Suitable Cu powders are commercially available from a variety of suppliers, such as Mitsui Mining & Smelting Co., Ltd., of Japan, e.g. 1030 Cu powder or Y1400 Cu powder.

The solder powder has a lower melting temperature (i.e., melting point) than a melting temperature of the metal powder. Such temperatures for the metal powder are described above. In certain embodiments, the solder powder has a melting temperature of no greater than about 300, no greater than about 275, no greater than about 250, or no greater than about 225, ° C.

Typically, the solder powder includes at least one metal selected from the group of tin (Sn), bismuth, zinc, gallium, indium, tellurium, thallium, antimony, selenium, and/or an alloy of two or more of these metals. In various embodiments, the solder powder comprises Sn, or at least one Sn alloy. In certain embodiments, the solder powder comprises two different alloys, alternatively more than two different alloys. For example, the solder powder can comprise a tin-bismuth (SnBi) alloy, a tin-silver (SnAg) alloy, or a combination thereof. The “combination” may simply be a combination of different metals, different alloys, or different metal(s) and alloy(s). In other embodiments, the solder powder may comprise SnPb.

In certain embodiments, the solder powder comprises Sn42/Bi58, Sn96.5/Ag3.5, or a combination thereof. Such alloy nomenclature generally indicates the amount of each metal by mass. Sn42/Bi58 generally has a melting temperature of about 138° C., and Sn96.5/Ag3.5 generally has a melting temperature of about 221° C. These alloys may be referred to in the art as “Alloy 281” and “Alloy 121”, respectively. Typically, the solder powder has a particle size of from about 0.05 to about 25, about 2.5 to about 25, about 5 to about 20, about 5 to about 15, or about 10, μm on average. Various PSDs, and modes thereof, can be utilized. Suitable solder powders are commercially available from a variety of suppliers, such as Indium Corporation of America of Elk Grove Village, Ill.

The solder is useful for suppressing oxidation of the metal powder, especially after formation of the conductor. It is believed that the solder also enhances wetting of supplemental solders and facilitates strong solder joint formation during soldering operations employing the conductor. As described further below, the solder powder, upon melting, generally fuses particles of the metal powder together prior to the composition reaching a final cure state. Such melting and fusing forms electrically conductive bridges in the conductor during formation.

The metal and solder powders can be present in the composition in various amounts. Typically, the metal and solder powders are collectively present in an amount (or a combined amount) of from about 50 to about 95, about 80 to about 95, about 80 to about 90, or about 85, wt %, each based on the total weight of the composition Typically, the metal powder is present in the composition in an individual amount of from about 35 to about 85, about 35 to about 65, about 40 to about 55, about 40 to about 50, or about 45, wt %, each based on the total weight of the composition. Typically, the solder powder is present in the composition in an individual amount of from about 25 to about 75, about 25 to about 55, about 30 to about 50, about 35 to about 45, or about 40, wt %, each based on the total weight of the composition.

The polymer can comprise various types of polymers, or a monomer which is polymerisable to yield the polymer. The polymer is generally a thermosetting resin, such as an epoxy, an acrylic, a silicone, a polyurethane, or combinations thereof. In certain embodiments, the polymer comprises an epoxy resin, which could also be a “B stage” resin. Examples of epoxy resins include diglycidyl ethers of bisphenol A, and diglycidyl ethers of bisphenol F.

In embodiments where the polymer comprises (or is) an epoxy resin, the epoxy resin can be of various epoxide equivalent weights (EEW). In certain embodiments, the epoxy resin has an EEW of from about 20 to about 100,000, about 30 to about 50,000, about 35 to about 25,000, about 40 to about 10,000, about 150 to about 7,500, about 170 to about 5,000, about 250 to about 2,500, about 300 to about 2,000, about 312 to about 1,590, about 400 to about 1,000, or about 450 to about 600, g/eq. EEW may be determined via methods understood in the art, such as by ASTM D1652.

Suitable examples of epoxy resins are commercially available from Dow Chemical of Midland, Mich., under the trademark D.E.R.™, such as D.E.R.™ 383, 6116, 662 UH, 331, 323, 354, 736, 732, 324, 353, 667E, 668-20, 671-X70, 671-X75, 684-EK40, 6225, 6155, 669E, 660-MAK80, 660-PA80, 337-X80, 337-X90, 660-X80, 661-A80, 671-PM75, 3680-X90, 6510HT, 330, 332, 6224, 6330-A10, 642U, 661, 662E, 663U, 663UE, 664U, 672U, 664UM, 667-20, 669-20, 671-R75, 671-T75, 671-XM75, and/or 692H. Other suitable epoxy resins are commercially available from Huntsman and Momentive under the trademarks Araldite® and Epikote™.

The polymer generally functions as a binder which improves the adherence of the conductor to a substrate after curing, and increases overall cohesive strength of the conductor. In general, the conductor has excellent adhesive and cohesive properties. It is believed that during/after cure, the polymer provides adhesion between the conductor and the substrate at an interface (or interfaces) there between, and also provides cohesion between internal components of the conductor, e.g. the metal powder. The polymer can stick to a variety of difference surfaces, including solderable and non-solderable surfaces. The polymer also presents a portion of the metal powder opposite the substrate interface for direct soldering purposes, e.g. for tabbing. Prior to reaching a final cure state, the polymer also acts as a medium for delivering fluxes to the metal powder, as described further below.

The carboxylated-polymer can comprises various types of polymers and copolymers having one or more carboxyl (—COOH) groups, typically two or more carboxyl groups, such that the conductor generally has a cross-linked structure. The —COOH group (or groups) generally act as flux, are reactive with other groups in the composition (e.g. epoxy groups of the polymer), and/or form salts with metal oxides thus promoting cure (e.g. catalyzing epoxy cure). Examples of these carboxylated-polymers include those resulting from the polymerization or co-polymerization via anionic mechanism or radical mechanism of unsaturated aliphatic or aromatic acids, possibly in combination with unsaturated aliphatic or aromatic hydrocarbons, such as alkenes, alkynes, and/or arylenes. Suitable unsaturated carboxylic acids include aliphatic carboxylic acids, such as methacrylic acid, halogenoacrylic acid, crotonic acid, carboxyethylacrylate, acrylic acid, fumaric acid, itaconic acid, muconic acid, propargylacetic acid, and/or acetylendicarboxylic acid; and unsaturated aromatic acids, such as vinylbenzoic acid and/or phenylpropynoic acid. Suitable unsaturated alkenes in combination with unsaturated acids to form carboxylated co-polymers include propylene, isobutylene, vinylchloride, and/or styrene. Other examples of suitable carboxylated-polymers include carboxylic acid functional polyester resins and carboxylic acid anhydrides and polymers made thereof.

The carboxylated-polymer can be of various acid equivalent weights (AEW). In certain embodiments, the carboxylated-polymer has an AEW of from about 20 to about 100,000, about 25 to about 50,000, about 30 to about 25,000, about 30 to about 10,000, about 30 to about 5,000, about 30 to about 2,500, about 30 to about 2,000, about 40 to about 1,000, or about 50 to about 500, g/eq. AEW may be determined via methods understood in the art, such as by dividing molecular weight by the number of carboxyl groups and/or by ASTM D1980 to determine an acid value.

The carboxylated-polymer is useful for fluxing the metal powder and for cross-linking the polymer to form the conductor. Specifically, during heating of the composition to form the conductor, the carboxylated-polymer generally fluxes the metal powder at a first temperature, and serves as a cross-linking agent for the polymer at a second temperature, which is generally higher than the first temperature. These temperatures can vary, but generally fall within the temperature ranges described herein.

While serving as a fluxing agent for the metal powder, the carboxylated-polymer generally dissolves metal oxide on the surface of the metal. Removal of the metal oxide permits the metal particles to group (or agglomerate) and better form conductive bridges in the conductor during formation, especially in the case of solder-Cu bonding. Typically, the metal powder is fluxed in-situ during formation of the conductor, such that pre-fluxing of the metal powder prior to use is not necessary. For example, a pre-fluxer/cleaner, e.g. an acid, is not required to remove oxides from surface of the metal powder prior to use in the composition. In certain embodiments, the invention lacks prefluxer/prefluxing.

Furthermore, the removed metal oxide is generally present in sufficient quantity to catalyze the reaction between the polymer and the carboxyl groups of the carboxylated-polymer at elevated temperatures. The metal oxide can initially be imparted by heating the metal powder, which oxidizes to form oxides. The oxides can react with the carboxylated-polymer to from salts. The oxides and salts can serve as catalysts for the reaction of the polymer and carboxylated-polymer. Additionally catalysts may be made available with the thermal release of chelating agent which may have been used to treat the metal powder(s). Various catalysts can be liberated based on the type of metal and/or solder powder, such as organic tin and copper salts, benzotriazole, imidazole, etc. These various mechanisms generally occur after application of the composition and during formation of the conductor. These mechanisms interrelate to melting, wet-out, fluxing, and cure temperatures or profiles of the composition/components thereof.

In certain embodiments, the carboxylated-polymer comprises an acrylic polymer. In further embodiments, the carboxylated-polymer comprises a styrene-acrylic copolymer. In specific embodiments, the carboxylated-polymer is thermally stable at 215° C., has an acid number greater than 200, and/or a viscosity of less than 0.01 Pa·s (10 centipoise) at 20° C. Examples of suitable acrylic polymers are commercially available from BASF Corp. of Florham Park, N.J., under the trademark Joncryl®, such as Joncryl® 50, 60, 61, 63, 67, 74-A, 77, 89, 95, 142, 500, 504, 507, 508, 510, 530, 537, 538-A, 550, 551, 552, 556, 558, 581, 585, 587, 611, 624, 631, 633, 646, 655, 660, 678, 680, 682, 683, 690, 693, 690, 693, 750, 804, 815, 817, 819, 820, 821, 822, 843, 845, 848, 901, 902, 903, 906, 906-AC, 909, 911, 915, 918, 920, 922, 924, 934, 935, 939, 942, 945, 948, 960, 963, 1163, 1520, 1522, 1532, 1536, 1540, 1610, 1612, 1655, 1670, 1680, 1695, 1907, 1908, 1915, 1916, 1919, 1954, 1980, 1982, 1984, 1987, 1992, 1993, 2153, 2178, 2350, 2561, 2570, 2640, 2646, 2660, 2664, 8383, and/or HR 1620.

Typically, the polymer and the carboxylated-polymer are collectively present in the composition an amount of from about 2.5 to about 10, about 2.5 to about 7.5, about 3 to about 6, about 5 to about 6, or about 5.5, wt %, each based on the total weight of the composition. In certain embodiments, the polymer and carboxylated-polymer are in a weight ratio of from about 1:1 to about 1:3, about 1:1 to about 1:2.75, about 1:1 to about 1:2.5, or about 1:1.5 to about 1:2.5, (polymer:carboxylated-polymer).

Typically, the polymer is present in the composition an amount of from about 0.5 to about 5, about 1 to about 2.5, about 1.5 to about 2, or about 1.75, wt %, each based on the total weight of the composition. Typically, the carboxylated-polymer is present in the composition an amount of from about 1 to about 7.5, about 2 to about 5, about 3 about 4, or about 3.5 to about 4, wt %, each based on the total weight of the composition.

The dicarboxylic acid is also useful for fluxing the metal powder, in addition to the carboxylated-polymer. Various types of dicarboxylic acids can be utilized. Examples of suitable dicarboxylic acids include linear, cyclic, aromatic and/or highly branched alkyl and/or unsaturated aliphatic and/or aryl dicarboxylic acid such as oxalic acid, malonic acid, succinic acid, glutaric acid, adipic acid, pimelic acid, suberic acid, azelaic acid, sebacic acid, undecanedioic acid, dodecanedioic acid, maleic acid, glutaconic acid, traumatic acid, muconic acid, phthalic acid, isophthalic, and/or terephthalic acid. In certain embodiments, the dicarboxylic acid is dodecanedioic acid (DDDA). Typically, the dicarboxylic acid is present in the composition in an amount of from about 0.05 to about 1, about 0.1 to about 0.75, about 0.2 to about 0.5, or about 0.2 to about 0.3, wt %, each based on the total weight of the composition.

The monocarboxylic acid is also useful for fluxing the metal powder, in addition to the carboxylated-polymer and the dicarboxylic acid. Specifically, the monocarboxylic is useful for preventing premature cure of the composition from metal oxides that may be already present or formed at ambient temperature. Various types of monocarboxylic acids can be utilized. Examples of suitable monocarboxylic acids include linear, cyclic, aromatic and/or highly branched alkyl and/or unsaturated aliphatic and/or aryl monocarboxylic acids such as formic acid, acetic acid, halogenoacetic acid, propionic acid, butyric acid, valeric acid, caproic acid, caprylic acid, lauric acid, decanoic acid, palmitic acid, stearic acid, icosanoic acid, isobutyric acid, isopentanoic acid, neopentanoic acid, neodecanoic acid, isostearic acid, oleinic acid, nervonic acid, linoleic acid octynoic acid, benzoic acid, and/or phenylpropynoic acid. In various embodiments, the monocarboxylic acid is a versatic acid. In certain embodiments, the monocarboxylic acid is Versatic 10, which is a synthetic acid comprising a mixture of highly branched isomers of C₁₀ monocarboxylic acids, mostly of tertiary structure. Versatic 10 may also be referred to in the art as neodecanoic acid. Examples of suitable monocarboxylic acids are commercially available from Hexion Specialty Chemicals of Carpentersville, Ill.

It is believed that the high degree of branching in the monocarboxylic acid gives rise to steric hindrance which imparts salts formed therefrom with excellent stability. In certain embodiments, the monocarboxylic acid is liquid at room temperature (RT; ˜20 to 25° C.). Typically, the monocarboxylic acid is present in the composition an amount of from about 0.25 to about 1.25, about 0.25 to about 1, about 0.25 to about 0.75, about 0.4 to about 0.5, or about 0.45, wt %, each based on the total weight of the composition.

In embodiments where the polymer comprises an epoxy resin such that epoxy groups are provided, the ratio of acidic groups (provided by the acids) to epoxy groups is generally of from about 1:1 to about 10:1, about 2:1 to about 9:1, about 3:1 to about 8:1, about 4:1 to about 7:1, about 5:1 to about 7:1, or about 6:1 to about 7:1, acidic:epoxy (A:E). In further embodiments, the ratio of acidic groups to epoxy groups is generally at least about 3:1, at least about 3.5:1, at least about 4:1, at least about 4.5:1, at least about 5:1, at least about 5.5:1, at least about 6:1, at least about 6.5:1, or at least about 7:1, A:E.

Without being bound or limited to any particular theory, it is believed that increasing the A:E ratio, e.g. above about 4:1, provides for excellent fluxing of the metal powder without the need for pre-fluxing of the metal powder. At lower ratios, e.g. less than about 4:1 A:E, it is believed that the composition will not be directly solderable due to insufficient fluxing of the metal powder. Specifically, in certain embodiments, at a A:E below about 4:1, fluxing may not occur, which can be determined via color change during heating/cure. In addition, at such lower levels, the solder powder may not wet out and/or be solderable, even with fluxing. Generally, a color change (or shift) from brown to light to dark grey indicates sufficient fluxing or fluxed materials. As such, if the material remains brown (or brown like, e.g. coppery colored) after attempting to flux the material, then fluxing did not occur or was insufficient. It is believed that the material turns grey after fluxing due to wetting out of the metal powder, e.g. Cu, surface with the solder such that you effectively only see the solder. In situations where fluxing is insufficient, the surface of metal powder is not completely wet out with the solder such that it is still visible.

In certain embodiments, the composition can further comprise an additive. Various types of additives can be utilized. Examples of suitable additives include solvents, adhesion promoters, defoamers, deactivators, anti-oxidants, rheology enhancers/modifiers, and/or thermal agents. Further examples of suitable components, useful for forming various embodiments of the composition, are disclosed in U.S. Pat. No. 7,022,266 to Craig, and in U.S. Pat. No. 6,971,163 to Craig et al., both of which are incorporated herein by reference in their entirety to the extent they do not conflict with the general scope of the invention.

If utilized, solvents can be useful for cutting the polymer and/or carboxylated-polymer into solution. Solvents can also be useful for adjusting viscosity of one or more of the components, and/or for adjusting rheology of the composition itself. Adjusting viscosity of the composition can be useful for various purposes, e.g. for obtaining a desired viscosity should the composition be applied via printing or similar technique. Various types of solvents can be utilized. Examples of suitable solvents include alcohols, such as monoterpene alcohol (e.g. terpineol), and benzyl alcohol. Further examples include 2-ethoxyethyl acetate, 2(3)-(Tetrahydrofurfuryloxy)tetrahydropyran, diisobutyl ketone, propylene glycol monomethyl ether acetate (PGMEA) and propylene glycol-1,2 propanediol. Such solvents are commercially available from various sources, such as Sigma Aldrich of Chicago, Ill. Another suitable solvent is butyl carbitol, which is commercially available from Dow Chemical. Various combinations of solvents can be utilized. The solvent can be used in various amounts. In certain embodiments, the solvent(s) is present in the composition in an amount of from about 0.5 to about 15, about 1 to about 12.5, about 2.5 to about 10, about 5 to about 7.5, or about 5 to about 7, wt %, each based on the total weight of the composition. Depending on application technique, the solvent may be added in a predetermined amount and/or added as needed.

If utilized, adhesion promoters are useful for further increasing adhesion of the conductor on various substrates. Various types of adhesion promoters can be utilized. Examples of suitable adhesion promoters (or coupling agents) include those based on silane and/or titanate. Employing silane adhesion promoters is useful for increasing adhesion to substrates having organic functionalities. Employing titanate adhesion promoters is useful for increasing adhesion to substrates having inorganic fillers. It is believed that the titanate coupling agent couples to the surface of inorganic fillers to improve the compatibility with an organic matrix and also improves adhesion to the substrate. A combination of different promoters can be used. In certain embodiments, the adhesion promoter, e.g. titanate, is reactive with at least one of the polymers of the composition. Examples of suitable adhesion promoters are commercially valuable from Dow Corning Corp. of Midland, Mich., such as 2-(3,4-epoxycyclohexyl)ethyl]trimethoxysilane, e.g. Z-6043, or glycidoxypropyltrimethoxysilane, e.g. Z-6040. Further suitable examples include those commercially available from Momentive under the trademark Silquest, such as Silquest A-187; from Xiameter, such as Xiameter® OFS-6040; and from Kenrich Petrochemicals Co. of Bayonne, N.J., under the trademark Ken-React®, such as Ken-React® KR9S. While not required, the adhesion promoter can be used in various amounts. In certain embodiments, the adhesion promoter(s) is present in the composition in an amount of from about 0.01 to about 3, about 0.1 to about 2, about 0.25 to about 1, or about 0.8, wt %, each based on the total weight of the composition.

If utilized, defoamers are useful for preventing foaming during formation and/or use of the composition. Various types of defoamers can be utilized. Examples of suitable defoamers include silicone-free defoamers. Examples of suitable defoamers are commercially available from BYK additives & instruments of Wallingford, Conn., such as BYK®-052. While not required, the defoamer can be used in various amounts. In certain embodiments, the defoamer(s) is present in the composition in an amount of from about 0.01 to about 1, about 0.1 to about 0.75, about 0.1 to about 0.5, or about 0.1 to about 0.3, wt %, each based on the total weight of the composition.

If utilized, deactivators and/or anti-oxidants are useful for suppressing migration of metals, e.g. Cu. Various types of deactivators and/or anti-oxidants can be utilized. In one embodiment, the deactivator comprises oxalyl bis(benzylidenehydrazide). Examples of suitable deactivators and/or anti-oxidants are commercially available from Eastman Chemical Co. of Kingsport, Tenn., such as Eastman™ OABH Inhibitor. While not required, the deactivator and/or anti-oxidant can be used in various amounts. In certain embodiments, the deactivator(s) is present in the composition in an amount of from about 0.01 to about 1, about 0.1 to about 0.75, about 0.1 to about 0.5, or about 0.1 to about 0.4, wt %, each based on the total weight of the composition.

In certain embodiments, the composition comprises a styrene dibromide. A specific example is 1,2 dibromoethyl benzene, which is commercially available from Sigma Aldrich. The styrene dibromide is useful for increasing thermal conductivity of the composition. In addition, the presence of a vinyl functional group allows the styrene to polymerize during formation of the conductor. While not required, the styrene dibromide can be used in various amounts. In certain embodiments, the styrene dibromide is present in the composition in an amount of from about 0.05 to about 1, about 0.1 to about 0.75, about 0.1 to about 0.5, or about 0.2 to about 0.3, wt %, each based on the total weight of the composition.

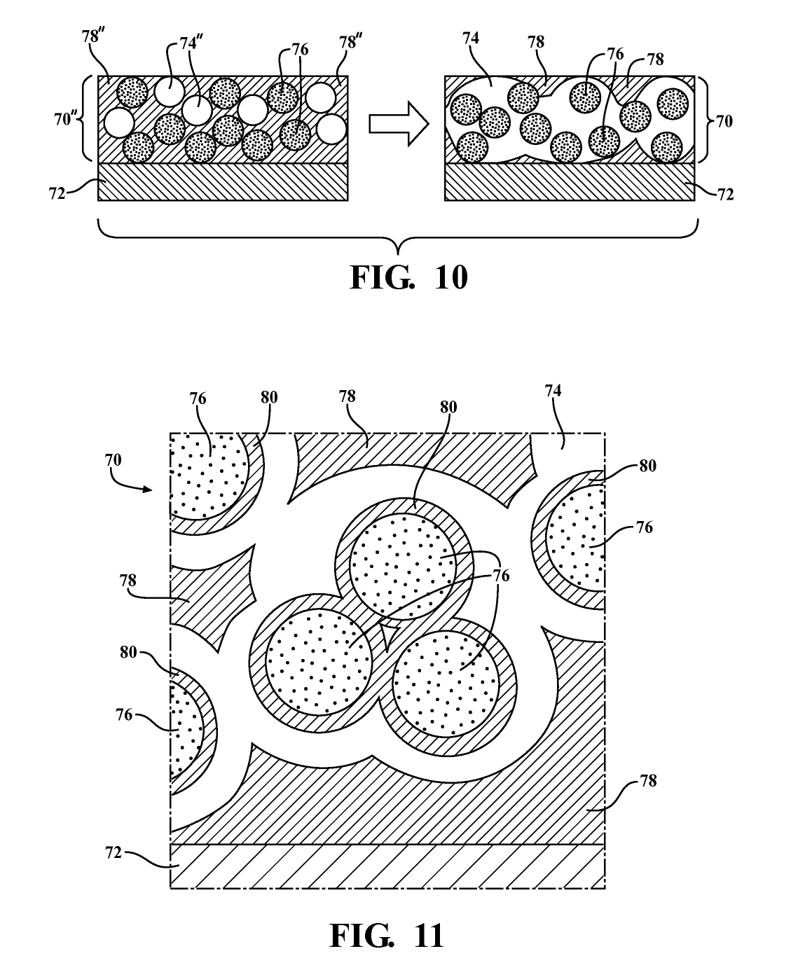

Referring to FIG. 10, the composition 70″ is disposed on a substrate 72 and is generally shown “pre-cured” on the left, and “cured” on the right such that it is the conductor 70. As used herein, a quotation mark (“) generally indicates a different state of the respective component or composition, such as prior to curing, prior to sintering, etc., whereas lack of the” generally indicates a post or final cure state of the respective component or composition. As alluded to above, the conductor 70 is useful for current transport and/or electrical connections for a variety of applications. The composition 70″ and conductor 70 is not limited to any particular application. The composition 70″ can be used to form various articles. Such articles generally include a substrate 72 with the conductor 70 disposed on the substrate 72. The substrate 72 can be formed from various materials. In one embodiment, the substrate 72 is also a conductor itself. Examples of such conductive substrates 72 include metals and semi-conductors. Specific examples of metal substrates 72 include Al, Ag, or combinations thereof. Examples of semi-conductor substrates 72 include those formed from silicon, such as crystalline silicon. In other embodiments, the substrate 72 is a dielectric (or insulator). The composition 70″ can be disposed on a variety of materials, including combinations of those described above. Examples of other specific materials include both solderable and non-solderable metals, such as high melting point conductive metals, e.g. nickel or a conventional bulk substrate. In general, only metallic materials are considered to be solderable.

The conductor 70 can take various forms, and be of various sizes and shapes, such as being configured for use as a busbar, a contact pad, a fine line, a finger, and/or an electrode. For example, the composition 70″ can be used to form fine lines, e.g. 70 μm lines, dots, dots and lines, etc., by printing or other means. Other widths can also be formed. The conductor 70 is not limited to any particular shape or configuration. Some of the aforementioned components are useful for PV cells and other PV devices, which are described further below. The composition 70″ can be for other applications as well, such as for circuit boards, e.g. printed circuit board (PCB) production, or other applications requiring a conductive material. The conductor 70 is directly solderable, which provides improved connection means, such as by using tabbing to directly connect to the conductor 70. Said another way, typically there is no topcoat, protective, or outermost layer which needs to be removed from the conductor 70 prior to soldering directly thereto. This provides for reduced manufacturing time, complexity, and cost. For example, tabbing can be directly soldered to the conductor 70 without the need for additional steps to be taken. In certain embodiments, an exception to this may be an additional fluxing step. In general, a surface is directly solderable if solder can be wet out on the surface after processing. For example, if one can either directly solder a wire to a substrate (within a commercially reasonable time frame and typically using an applied flux), use a tinned soldering iron to place a solder layer on the busbar, or simply heat up the substrate and see the solder wet out the electrode surface, the material would be directly solderable. In the case of a non-solderable system, even after applying flux and extensive heating, the solder never wets the surface, and no solder joint can be made.

In certain embodiments, the composition 70″ can be used as an adhesive by relying on its curing mechanism to form the conductor 70. For example, the composition 70″ can be applied and heated to form the conductor 70, and the conductor 70 can serve as an adhesive, such as holding a wire in place, holding two substrates together, etc. The wire can be disposed in the composition 70″ and/or the composition 70″ can be disposed on the wire, and subsequently cured to form the conductor 70, thereby holding the wire in place. Prior to final cure to form the conductor 70, the instant or intermediate adhesion strength provided by the composition 70″ may be referred to as green strength. In other embodiments, one of more of the fingers 40a, a second electrode 62 (as described below), or combinations thereof are formed from the invention composition 70″.

A method of forming the conductor 70 typically includes the step of applying the composition 70″ to the substrate 72. The composition 70″ can be applied by various methods. Various types of deposition methods can be utilized, such as printing through screen or stencil, or other methods such as aerosol, ink jet, gravure, or flexographic, printing. In certain embodiments, the composition 70″ is screen printed directly onto the substrate 72. The composition 70″ is generally in the form of a paste, as such, printing is one method that can readily be utilized. The composition 70″ can be applied to the substrate 72 to make direct physical and electrical contact to the substrate 72.

As described above, the solder powder 74″ of the composition 70″ melts at lower temperature than melting temperature of the metal powder 76 of the composition 70″. The composition 70″ further comprises the polymers and other components 78″, as described above. The method further comprises the step of heating the composition 70″ to a temperature of no greater than about 800° C. to form the conductor 70. The composition 70″ is generally heated to a temperature of from about 150 to about 800, about 175 to about 275, about 700 to about 250, or about 725, ° C. In certain embodiments, the composition 70″ is heated at about 250° C. or less to form the conductor 70. In certain embodiments, the composition 70″ is heated to a temperature of from about 700 to about 800° C. Such temperature generally sinters the solder powder 74″, but does not sinter the metal powder 76, to form the conductor 70. Such heating may also be referred to in the art as reflow or sintering.

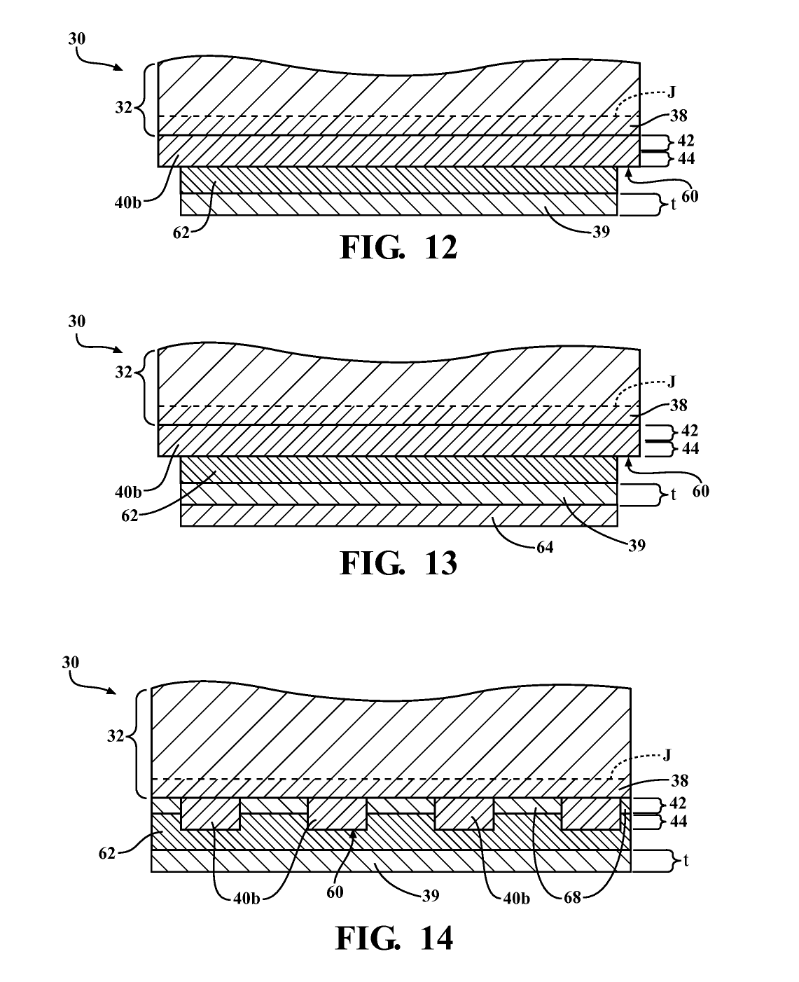

Referring to FIGS. 10 and 11, it is believed that the solder powder 74″ sinters and coats particles of the metal powder 76 during heating of the composition 70″ to form the conductor 70. Also during this time, the composition 70″ can lose volatiles and the polymers 78″ crosslink to a final cured state 78, generally providing adhesion to the substrate 72. As shown in FIG. 11, at least a portion of the polymer 78 is in direct contact with the substrate 72. An inter-metallic layer 80 generally forms around particles of the metal powder 76. Such coating enables the solder 74 coated particles of metal powder 76 to carry current, and can also prevent oxidation of metal powder 76. Due to the lower temperatures, the metal powder 76 does not generally sinter during the heating. The low temperature of this heating step generally allows for the use of temperature sensitive substrates 72, e.g. amorphous silicon or transparent conductive oxides.

The composition 70″ can be heated for various amounts of time to form the conductor 70. Typically, the composition 70″ is heated only for the period of time required for the conductor 70 to form. Such times can be determined via routine experimentation. An inert gas, e.g. a nitrogen (N₂) gas blanket, can be used to prevent premature oxidation of the metal powder 76 prior to being coated with the solder 74″. However, pre-fluxing of the metal powder 76 is generally not required. Unnecessarily overheating the conductor 70 for longer periods of time may damage the substrate 72 and/or the conductor 70.

Without being bound or limited by any particular theory, it is believed that the composition 70″ is generally self fluxing and oxidation resistant based on the following mechanism: heat onset activates the carboxylated-polymer to flux the solder and metal powders 74″, 76. Released metallic oxides and salts, act as a catalyst and promote rapid cross linking between the polymer and the carboxylated-polymer at a higher temperature. The catalyzing oxides evolve from native metal, e.g. Cu, oxidation. The metallic salts are either produced from the reaction between the oxides and the carboxylated-polymer or are compounds used as lubricants/stability enhancers which have been released as a result of the solder and metal powders 74″, 76 heating. In addition to the fluxing/cross-linking mechanisms, as the temperature increases, the solder powder 74″ melts and wets the particles of metal powder 76 and a sintering between the metal powder 76 and the solder powder 74 occurs as shown in FIG. 10 to form the inter-metallic layer 80. The solder coating 74 on the particles of the metal powder 76 is beneficial for preventing further oxidation of the metal powder 76 and maintaining conductivity of the conductor 70 over time.

As alluded to above, and without being bound or limited by any particular theory, it is believed that physical separation of the busbar 52 and the upper doped region 34 is beneficial for at least two reasons. First, such separation prevents diffusion of the second metal, e.g. Cu, into the base substrate 32. It is believed that preventing such diffusion prevents the opposite doped region from being shunted by the second metal of the busbar 52. Second, such physical separation is believed to reduce minority carrier recombination at the metal and silicon interfaces. It is believed that by reducing the area of metal/silicon interface, loss due to recombination is generally reduced and open-circuit voltage (V_{OC}) and short-circuit current density (J_{SC}) are generally improved. The area is reduced due to the passivation layer 54 being disposed between much of the busbar 52 and the upper doped region 34, with the collector 40, or fingers 40a if present, being the only metal components in contact with the upper doped region 34 of the base substrate 32. Additional embodiments of the PV cell 30 will now be described immediately below.

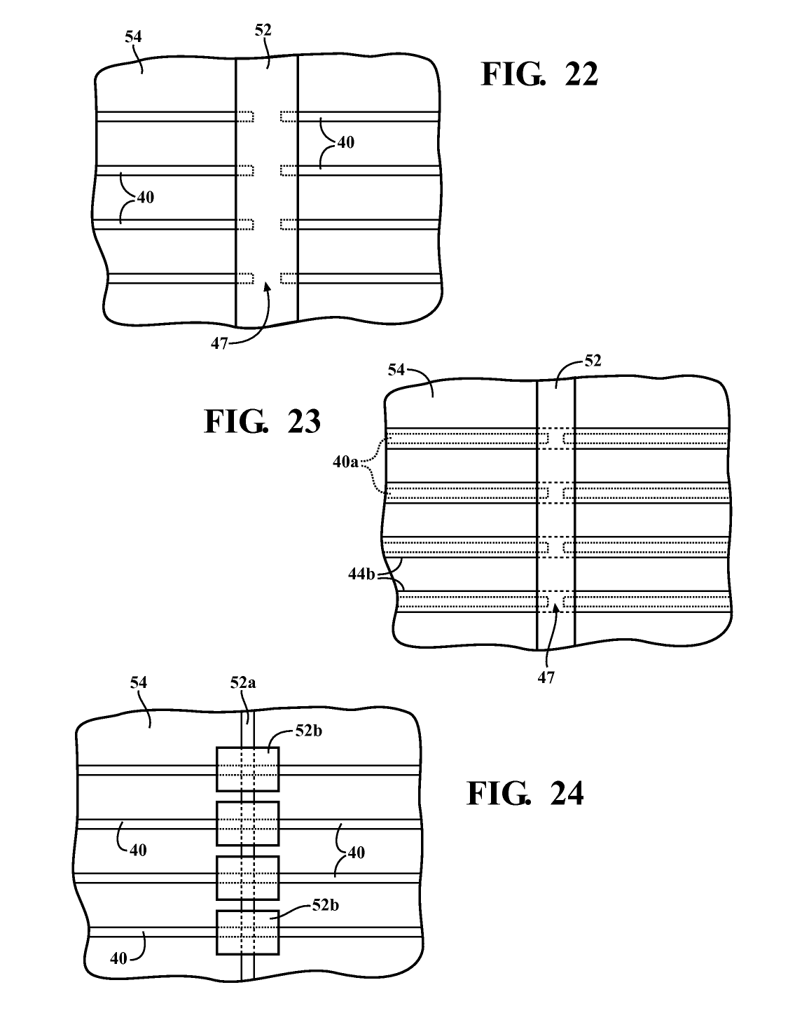

The PV cell 30 of FIG. 22 is similar to that of FIG. 3A, but includes discontinuous-fingers 40. The busbar 52 is disposed over a gap 47 defined between the fingers 40. The gap 47 can be of various widths, provided the busbar 52 is in electrical contact with the fingers 40. The fingers 40 may comprise a majority of one metal, e.g. Ag, whereas the busbar 52 another metal, e.g. Cu (as like described above). By having gaps 47, cost of manufacture can be reduced (such as by reducing the total amount of Ag utilized), and/or adhesion may be positively impacted.

The PV cell 30 of FIG. 23 is similar to that of FIG. 22, but further includes supplemental fingers 40b disposed over the fingers 40a. The supplemental fingers 40b may comprise the same material as the busbar 52, e.g. Cu, or a different material. The supplemental fingers 40b and the busbar 52 may be separate (e.g. one lying over the other) or unitary. By utilizing the supplemental fingers 40b, the size of the fingers 40a (e.g. Ag fingers) can be reduced, which can reduce cost of manufacture and/or improve adhesion.

The PV cell 30 of FIG. 24 includes fingers 40, busbar 52a, and supplemental busbar pads 52b disposed over the fingers 40 and busbar 52a. The fingers 40 and busbar 52 may be separate or unitary. The fingers 40 and busbar 52 may comprise the same majority metal, e.g. Ag, or be different than each other. The busbar pads 52b can comprise Cu or another metal, e.g. when formed from the invention composition. By utilizing the busbar pads 52b, the size of the busbar 50a (e.g. Ag busbar 52a) can be reduced.

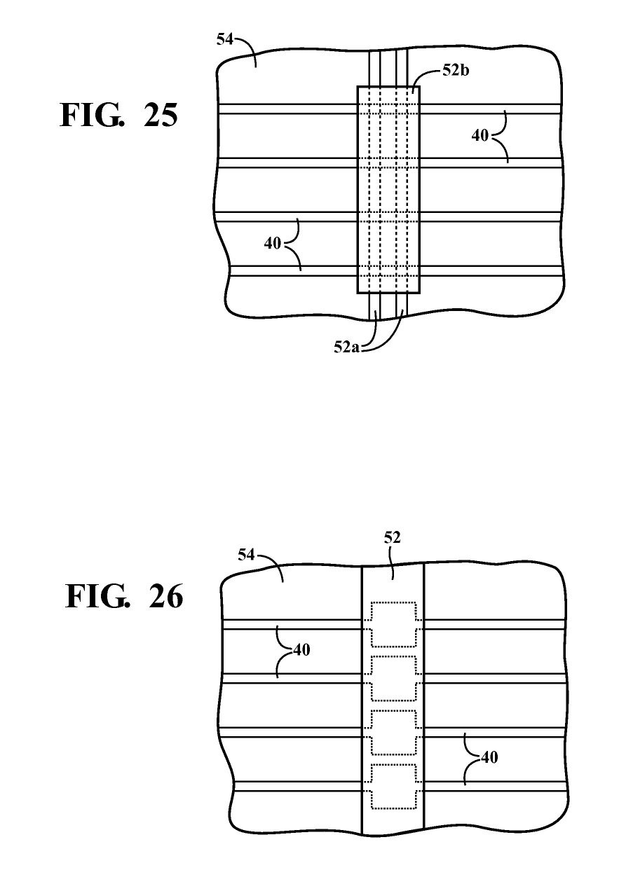

The PV cell 30 of FIG. 25 is similar to that of FIGS. 22 and 24, but includes a pair of busbars 52a and a supplemental busbar 52b disposed over the busbars 52a. The fingers 40 and busbars 52a can be separate or unitary. The fingers 40 and busbar 52a may comprise the same majority metal, e.g. Ag, or be different than each other. The supplemental busbar 52b can comprise Cu or another metal. By utilizing the supplemental busbar 52b, the size of the busbars 52a can be reduced.

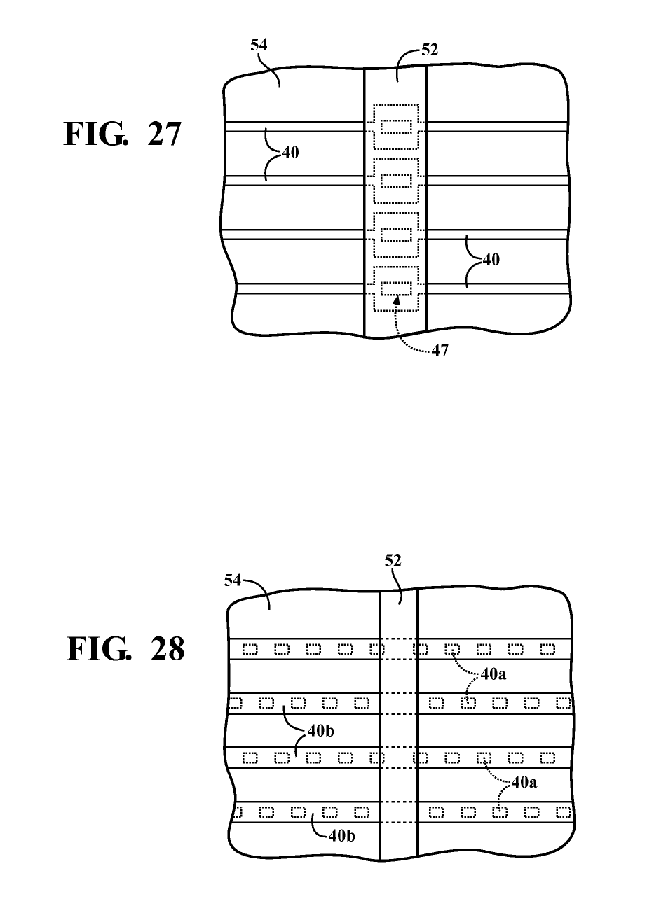

The PV cells 30 of FIGS. 26 and 27 are similar to that of FIG. 22, but include fingers 40 having pads in place of the gaps 47. The padded fingers 40 can help to improve electrical contact to the busbar 52, and adhesion, while reducing the amount of Ag used and reducing manufacturing cost. The fingers 40 of FIG. 26 have hollow pads, i.e., internal gaps 47, which can reduce cost of manufacture and positively impact adhesion. A portion of the busbar 52 may be disposed in the gaps 47 of the hollow padded fingers 40.

The PV cell 30 of FIG. 28 is similar to that of FIG. 22, but includes discontinuous-fingers 40a with supplemental fingers 40b disposed thereon. The discontinuous-fingers 40a can be in various shapes, such as rectangles, squares, dots, or combinations thereof. Such fingers 40a can be plated, printed, or formed in another manner. A plurality of gaps 47 are defined by the discontinuous-fingers 40a. The supplemental fingers 40b and the busbar 52 may be separate or unitary. By utilizing the discontinuous-fingers 40a and supplemental fingers 40b, cost of manufacture can be reduced. The discontinuous-fingers 40a typically contact the emitter while the supplemental fingers 40b and busbar 52 carry current.

Further embodiments of various types of PV cells 30, which can include the invention electrically conductive layer, are described in co-pending Serial No. PCT/US12/69465 (Attorney Docket No. DC11371 PSP1; 071038.01087), in co-pending Serial No. PCT/US12/69492 (Attorney Docket No. DC11372 PSP1; 071038.01089), and co-pending Serial No. PCT/US12/69503 (Attorney Docket No. DC11370 PSP1; 071038.01091), all filed concurrently with the subject application, the disclosures of which are incorporated by reference in their entirety to the extent they do not conflict with the general scope of the present invention.

Referring back to the PV cell 30, in one embodiment, the base substrate 32 includes a rear doped region 38, a collector 40 that is a first electrode 40b disposed on the rear doped region 38, opposite the upper doped region 34 (if present), and the electrically conductive layer 39 disposed adjacent the collector 40 that is the first electrode 40b.

The first electrode 40b has an electrode outer surface 60. The first electrode 40b may cover the entire rear doped region 38 or only a portion thereof. If the later, typically a passivation layer 54, e.g. a layer of SiNₓ, is used to protect exposed portions of the rear doped region 38, but the passivation layer 54 is not used between the first electrode 40b and the portion of rear doped region 38 in direct physical and electrical contact. The first electrode 40b may take the form of a layer, a layer having localized contacts, or a contact grid comprising fingers and busbars. Examples of suitable configurations include, but are not limited to, p-type base configurations, n-type base configurations, PERC or PERL type configurations, bifacial BSF type configurations, heterojunction with intrinsic thin layer (HIT) configurations, emitter wrap through (EWT) configurations, metal wrap through (MWT) configurations, interdigitated back contact (IBC) configurations, etc. The PV cell 30 is not limited to any particular type of first electrode 40b or electrode configuration.

The first electrode 40b may take the form of a layer, a layer having localized contacts, or a contact grid comprising fingers, dots, pads, and/or busbars. Examples of suitable configurations include p-type base configurations, n-type base configurations, PERC or PERL type configurations, bifacial BSF type configurations, heterojunction with intrinsic thin layer (HIT) configurations, etc. The PV cell 30 is not limited to any particular type of electrode or electrode configuration. The first electrode 40b can be of various thicknesses, such as from about 0.1 to about 500, about 1 to about 100, or from about 5 to about 50, μm thick on average. Some of these embodiments, as well as others, are described in detail below.

In certain embodiments, the first electrode 40b comprises a first metal, which is present in (each of) the first electrode(s) 40a in a majority amount. The first metal may comprise various types of metals. In certain embodiments, the first metal comprises Al. In other embodiments, the first metal comprises Ag. In yet other embodiments, the first metal comprises a combination of Ag and Al. By “majority amount”, it is generally meant that the first metal is the primary component of the first electrode 40b, such that it is present in an amount greater than any other component that may also be present in the first electrode 40b. In certain embodiments, such a majority amount of the first metal, e.g. Al and/or Ag, is generally greater than about 35, greater than about 45, or greater than about 50, wt %, each btw of the first electrode 40b.

In embodiments where the rear doped region 38 is a p-type, the first electrode 40b typically comprises at least one of the periodic table elements of group III, e.g. Al. Al can be used as a p-type dopant. For example, an Al paste can be applied to the base substrate 32 and then fired to form the first electrode 40b, while also forming the rear p⁺-type doped region 38. The Al paste can be applied by various methods, such as by a screen printing process. Other suitable methods are described below.

As best shown in FIGS. 12 through 17, a second electrode 62 is spaced from the rear doped region 38 of the base substrate 32. The rear doped region 38 is free of (direct) physical contact with the second electrode 62. The second electrode 62 is in electrical contact with the first electrode 40b. The second electrode 62 need only contact a portion of the first electrode 40b, or it can cover an entirety of the first electrode 40b. The first and second electrodes 40b, 62 may be referred to in the art as an electrode stack. The rear doped region 38 is in electrical communication with the second electrode 62 via the first electrode 40b. The second electrode 62 is typically configured in the shape of a pad(s), contact pad(s), or busbar(s). Reference to the second electrode 62 herein can refer to various configurations.

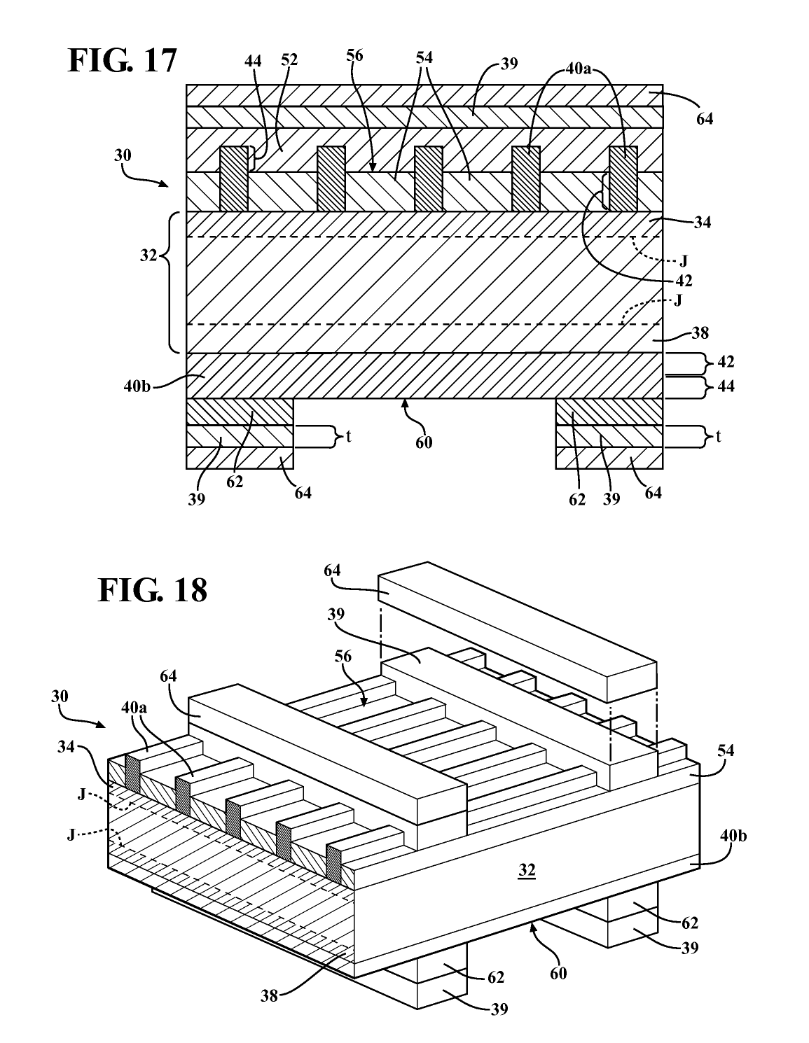

For example, as best shown in FIGS. 17 through 20, the PV cell 30 can include a pair of second electrodes 62, shaped as busbars, on the first electrode 40b. In addition, a pair of front busbars 52 is disposed opposite the second electrodes 62 in generally a mirror configuration. The second electrodes 62 and the busbars 52 can be the same or different from each other, both in chemical makeup and/or in physical characteristic, such as shape and size. The PV cell 30 can have two second electrodes 62. In certain embodiments, the PV cell 30 may have more than two second electrodes 62, such as three second electrodes 62, four second electrodes 62, six second electrodes 62, etc. Each second electrode 62 is in electrical contact with at least one first electrode 40b. The second electrodes 62 are useful for collecting current from the first electrode 40b which has collected current from the rear doped region 38. As shown generally, the second electrode 62 is disposed directly on the electrode outer surface 60 of the first electrode 40b to provide intimate physical and electrical contact thereto. This places the second electrode 62 in position for carrying current directly from the first electrode 40b. The first electrode 40b is in intimate physical and electrical contact with the rear doped region 38 of the base substrate 32. As alluded to above, in one embodiment a passivation/additional passivation layer 68 is disposed between the second electrode 62 and the rear doped region 38 such that the second electrode 62 is free of physical contact with said rear doped region 38 of said base substrate 32.

The second electrode 62 can be of various widths, such as from about 0.5 to about 10, about 1 to about 5, or about 2, mm wide on average. The second electrode 62 can be of various thicknesses, such as from about 0.1 to about 500, about 10 to about 250, about 30 to about 100, or about 30 to about 50, μm thick on average. The second electrode 62 can be spaced various distances apart.

The second electrode 62 can be formed from various materials. In one embodiment, the second electrode 62 is formed similar to or like to the busbars 52. The second electrode 62 can be formed in the same manner(s) as described above for the busbars 52.

The electrically conductive layer 39 is disposed on and in physical contact with the second electrode 62 opposite the collector 40 comprising the first electrode 40b. As previously described above, the electrically conductive layer 39 is suitable for electrically connecting multiple PV cells 30 in series. Accordingly, the ribbon 64 described above can be disposed on and in physical contact with the electrically conductive layer 39.

The PV cell 30 has a series resistance of less than about 25 milliOhm (mOhm) at 20 degrees Celsius (° C.), alternatively less that 20 mOhm at 20° C., alternatively less than 15 mOhm at 20° C., alternatively less than 12 mOhm at 20° C., and alternatively less than 10 mOhm at 20° C., as measured by a Berger I-V test station configured with a four points probe.

The present invention also provides an article 66 for an assembly of associated photovoltaic cells as best shown in FIG. 21. The article 66 comprises the ribbon 64 for carrying electric current and the electrically conductive layer 39, the descriptions of which are provided above. The article 66 is suitable for “drop-in” applications to connect one or more PV cells of any type. More specifically, the PV cells do not require the electrically conductive layer 39 as described herein in conjunction with use of the article 66. However, it is to be appreciated that the article 66 can be used with PV cells 30 having the electrically conductive layer 39 as described herein.

One method of forming the article 66 comprises the step of applying an electrically conductive composition including the solvent, as previously described herein, to the ribbon 64. The method further comprises the step of removing or substantially removing the solvent from the electrically conductive composition to form the article 66 comprising the electrically conductive layer 39 disposed on the ribbon 64. In another embodiment, the method of forming the article 66 comprises the step of applying an electrically conductive composition including the solvent, as previously described herein, to a film, e.g. a fluorosilicone coated polyethylene terephthalate release liner. In this embodiment, the method further comprises the step of removing or substantially removing the solvent from the electrically conductive composition to form the electrically conductive layer 39 and then applying the electrically conductive layer 39 to the ribbon 64 and removing the film to form the article 66 comprising the electrically conductive layer 39 disposed on the ribbon 64. Various types of removal methods can be utilized, such as heating, e.g. heating the electrically conductive composition in an oven.

The present invention also provides a method of forming a photovoltaic cell comprising the base substrate 32 comprising silicon and including at least one doped region 34,38, the collector 40 disposed on the doped region 34, 38 of the base substrate 32 and having the lower portion 42 in physical contact with the doped region 34, 38 of the base substrate 32, and the upper portion 44 opposite the lower portion 42, and the electrically conductive layer 39 which is electrically isotropic or anisotropic. The method comprising the steps of applying an electrically conductive composition including the solvent, as previously described herein, adjacent the collector 40. The method further comprises the step of removing or substantially removing the solvent from the electrically conductive composition to form the electrically conductive layer 39. Various types of removal methods can be utilized, such as heating. In another embodiment, the method comprises the steps of applying an electrically conductive composition including the solvent, as previously described herein, to a film, e.g. a fluorosilicone coated polyethylene terephthalate release liner. In this embodiment, the method further comprises the step of removing or substantially removing the solvent from the electrically conductive composition to form the electrically conductive layer 39 and then applying the electrically conductive layer 39 adjacent the collector 40 and removing the film to form the photovoltaic cell.

The following example, illustrating the PV of the present invention, is intended to illustrate and not to limit the invention.

Inventive Composition 1 is prepared by combining a composition with electrically conductive particles to form an electrically conductive composition wherein the electrically conductive particles are present in an amount of 80 wt %, btw of the electrically conductive composition. The balance of the electrically conductive composition comprises binder and solvent. If necessary, a solvent, in addition to any solvents already present in the composition, may be combined with the composition and the electrically conductive particles to further modify the rheology of the electrically conductive composition.

The composition is a dispersion of a polydimethysiloxane gum and a resin.

The electrically conductive particles are conventional silver flake having an average particle size of from about 0.1 to about 20 μm.

Inventive Example 1 is prepared by applying Inventive Composition 1 to a fluorosilicone coated polyethylene terephthalate release liner. Inventive Composition 1 is then heated in an oven to remove any solvent present in Inventive Composition 1 forming an electrically conductive layer. The electrically conductive layer is applied to a PV cell and the release liner is removed. A ribbon is pressed onto the electrically conductive layer and series resistance of the PV cell is measured using a Berger I-V test station. The PV cell is flash tested to determine the series resistance. Inventive Example 1 has a series resistance of 11.17 mOhm measured at 20° C.

The PV cell is a 5 inch square multicrystalline silicon photovoltaic cell.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

1. A photovoltaic cell comprising:
a base substrate comprising silicon and including at least one doped region;
a collector disposed on said doped region of said base substrate and having a lower portion in physical contact with said doped region of said base substrate and an upper portion opposite said lower portion; and
an electrically conductive layer which is electrically isotropic or anisotropic, said electrically conductive layer disposed adjacent said collector and comprising;
a binder, and
electrically conductive particles comprising at least one metal selected from the group consisting of Group 8 through Group 14 metals of the Periodic Table of Elements which impart isotropic or anisotropic electrical conductivity to said electrically conductive layer;
wherein said electrically conductive layer is in electrical communication with said base substrate via said collector.

2. The photovoltaic cell as set forth in claim 1, wherein said base substrate includes as said at least one doped region:
i) an upper doped region;
ii) a rear doped region; or
iii) an upper doped region and a rear doped region spaced from said upper doped region.

3. The photovoltaic cell as set forth in claim 1:
i) wherein said binder is selected from the group consisting essentially of organic compositions, silicone compositions, or combinations thereof; or
ii) wherein said binder is a silicone composition comprising an organopolysiloxane; and/or
iii) having a series resistance of less than about 25 milliOhm (mOhm) at 20 degrees Celsius (° C.);

4. The photovoltaic cell as set forth in claim 2:
wherein said base substrate includes said upper doped region and said collector is a plurality of fingers with each finger spaced from each other; and
wherein each finger has a lower portion in physical contact with said upper doped region of said base substrate, and an upper portion opposite said lower portion.

5. The photovoltaic cell as set forth in claim 4:
i) wherein said electrically conductive layer is disposed on and in physical contact with said upper portion of each of said fingers so that said base substrate is in indirect electrical communication with said electrically conductive layer via said fingers; and/or
ii) further comprising a busbar disposed between said electrically conductive layer and said upper doped region of said base substrate such that said busbar is in physical contact with said upper doped region and said upper portion of each of said fingers so that said base substrate is in indirect electrical communication with said electrically conductive layer via said fingers, said busbar, or both of said fingers and said busbar; and/or;
iii) further comprising a passivation layer disposed on said upper doped region of said base substrate and having an outer surface opposite said upper doped region wherein said upper portion of each of said fingers extends away from said upper doped region through said outer surface of said passivation layer so that said base substrate is in indirect electrical communication with said electrically conductive layer via said fingers.

6-7. (canceled)

8. The photovoltaic cell as set forth in claim 5, comprising said passivation layer iii), and further comprising a busbar disposed between said electrically conductive layer and said passivation layer and in physical contact with said upper portion of said fingers, with said busbar spaced from and free of physical contact with said upper doped region of said base substrate so that said base substrate is in indirect electrical communication with said electrically conductive layer sequentially via said fingers and said busbar.

9. The photovoltaic cell as set forth in claim 8, wherein said busbar is formed from an electrically conductive busbar composition comprising:
a metal powder;
a solder powder which has a lower melting temperature than a melting temperature of said metal powder;
a polymer;
a carboxylated-polymer different from said polymer for fluxing said metal powder and cross-linking said polymer;
a dicarboxylic acid for fluxing said metal powder; and
a monocarboxylic acid for fluxing said metal powder.

10. The photovoltaic cell as set forth in claim 2, further comprising an additional collector, wherein said base substrate includes said rear doped region and said additional collector is a first electrode disposed on and in physical contact with said rear doped region of said base substrate.

11. The photovoltaic cell as set forth in claim 2, wherein said base substrate includes said rear doped region and said collector is a first electrode in physical contact with said rear doped region of said base substrate.

12. The photovoltaic cell as set forth in claim 10, further comprising a second electrode disposed on said first electrode, with said second electrode opposite and spaced from said rear doped region of said base substrate such that said rear doped region of said base substrate is free of physical contact with said second electrode so that said base substrate is in indirect electrical communication with said second electrode via said first electrode.

13. The photovoltaic cell as set forth in claim 12, wherein said second electrode is formed from an electrically conductive busbar composition comprising:
a metal powder;
a solder powder which has a lower melting temperature than a melting temperature of said metal powder;
a polymer;
a carboxylated-polymer different from said polymer for fluxing said metal powder and cross-linking said polymer;
a dicarboxylic acid for fluxing said metal powder; and
a monocarboxylic acid for fluxing said metal powder.

14. The photovoltaic cell as set forth in claim 12, wherein said electrically conductive layer is also disposed on said second electrode, with said electrically conductive layer spaced from and opposite said first electrode.

15. The photovoltaic cell as set forth in claim 1, further comprising at least one ribbon disposed on and in physical contact with said electrically conductive layer.

16. A photovoltaic module comprising a plurality of said photovoltaic cells in electrical communication and as set forth in claim 1.

17. An article for an assembly of associated photovoltaic cells, said article comprising:
a ribbon for carrying electric current; and
an electrically conductive layer which is electrically isotropic or anisotropic and disposed on said ribbon for attaching said ribbon to the photovoltaic cells, with said electrically conductive layer comprising;
a binder, and
electrically conductive particles comprising at least one metal selected from the group consisting of Group 8 through Group 14 metals of the Periodic Table of Elements which impart isotropic or anisotropic electrical conductivity to said electrically conductive layer; and
wherein said electrically conductive layer is in direct electrical communication with said ribbon.

18. An electrically conductive silicone composition which is electrically isotropic or anisotropic for forming an electrically conductive layer in a photovoltaic cell, said electrically conductive silicone composition comprising:
a silicone composition; and
electrically conductive particles comprising at least one metal selected from the group consisting essentially of Group 8 through Group 14 metals of the Periodic Table of Elements which impart isotropic or anisotropic electrical conductivity to said electrically conductive silicone composition.

19. The electrically conductive silicone composition as set forth in claim 18, which is electrically:
i) isotropic and wherein said electrically conductive particles are present in an amount of from about 50 to about 90 percent by weight based on the total weight of said electrically conductive silicone composition; or
ii) anisotropic and wherein said electrically conductive particles are present in an amount of from about 0.1 to about 50 percent by weight based on the total weight of said electrically conductive silicone composition.

20. (canceled)

21. The electrically conductive silicone composition as set forth in claim 18, wherein:
i) an electrically conductive layer formed from said electrically conductive silicone composition has a resistivity from about 1·10⁻⁵ to about 5·10⁻³ Ohms centimeters (ohm-cm) at 20° C. as measured by a Berger I-V test station configured with a four points probe head or lines resistance probe head;
ii) said electrically conductive layer is a pressure sensitive adhesive; or
iii) both i) and ii).

22. (canceled)

23. A photovoltaic cell comprising an electrically conductive layer formed from said electrically conductive silicone composition as set forth in claim 18.

24. A method of forming a photovoltaic cell comprising a base substrate comprising silicon and including at least one doped region, a collector disposed on the doped region of the base substrate and having a lower portion in physical contact with the doped region of the base substrate, and an upper portion opposite the lower portion, and an electrically conductive layer which is electrically isotropic or anisotropic, said method comprising the steps of:
providing an electrically conductive composition comprising a binder, electrically conductive particles comprising at least one metal selected from the group consisting of Group 8 through Group 14 metals of the Periodic Table of Elements which impart isotropic or anisotropic electrical conductivity to the electrically conductive layer formed from the electrically conductive composition, and a solvent comprising a hydrocarbon having from 1 to 30 carbon atoms; and
removing or substantially removing the solvent from the electrically conductive composition to form the electrically conductive layer.
